(19) United States
(12) Patent Application Publication
(10) Pub. No.: US 2024/0339558 A1
(43) Pub. Date: Oct. 10, 2024

(54) LED TRANSFER DEVICE, LED TRANSFER METHOD AND METHOD FOR MANUFACTURING DISPLAY DEVICE USING THE SAME

(71) Applicant: LG Display Co., Ltd., Seoul (KR)

(72) Inventors: ChungHwan AN, Goyang-si (KR); Eunjeong SHIN, Paju-si (KR)

(21) Appl. No.: 18/627,116

(22) Filed: Apr. 4, 2024

(30) Foreign Application Priority Data
Apr. 7, 2023 (KR) 10-2023-0046269

(51) Int. Cl. H01L 33/00; H01L 21/68; H01L 21/683; H01L 25/16

(52) U.S. Cl. CPC H01L 33/0093; H01L 21/68; H01L 21/6838; H01L 25/167

(57) ABSTRACT

Provided is a transfer method of a light emitting diode. The transfer method of the light emitting diode includes bonding a wafer in which a plurality of light emitting diodes is formed and a donor; transferring the plurality of light emitting diodes to the donor and detaching the wafer and the donor, the detaching of the wafer and the donor includes loading the bonded wafer and donor on a stage and a support member, fixing one of outermost portions of the donor by a fixing member, fixing one surface of the wafer to a head, moving the stage and the fixing member to a Z-axis direction, and moving the wafer and the head to an X-axis direction. Accordingly, the wafer and the donor are detached by the linear separation method to reduce the defective transfer of the plurality of light emitting diodes.

### CROSS-REFERENCE TO RELATED APPLICATIONS

This application claims the priority of Korean Patent Application No. 10-2023-0046269 filed on Apr. 7, 2023, in the Korean Intellectual Property Office, the disclosure of which is incorporated herein by reference.

### BACKGROUND

### Technical Field

The present disclosure relates to a light emitting diode (LED) transfer device, an LED transfer method, and a method for manufacturing a display device using the same, and more particularly, to a transfer device and a transfer method of a light emitting diode, and a method for manufacturing a display device using the same with an improved yield when a plurality of LEDs is transferred.

### Description of the Related Art

As display devices which are used for a monitor of a computer, a television, a cellular phone, or the like, there are an organic light emitting display (OLED) device which is a self-emitting device, a liquid crystal display (LCD) device which requires a separate light source, and the like.

An applicable range of the display device is diversified to personal digital assistants as well as monitors of computers and televisions and a display device with a large display area and a reduced volume and weight is being studied.

Further, in recent years, a display device including an LED is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### BRIEF SUMMARY

Various embodiments of the present disclosure provide a transfer device and a transfer method of a light emitting diode and a method for manufacturing a display device using the same that reduce defects of a plurality of LEDs during a transferring process of transferring a plurality of LEDs from a wafer into a donor.

Various embodiments of the present disclosure provide a transfer device and a transfer method of a light emitting diode and a method for manufacturing a display device using the same with an improved alignment precision of a plurality of LEDs.

Various embodiments of the present disclosure provide a transfer device and a transfer method of a light emitting diode and a method for manufacturing a display device using the same that relieve a tensile stress of a donor by moving a wafer to an X-axis direction when a wafer and a donor are detached.

Various embodiments of the present disclosure provide a transfer device and a transfer method of a light emitting diode and a method for manufacturing a display device using the same that reduce or minimize surface-separation of a wafer and a donor in a latter part of a detaching process.

Still another object to be achieved by the present disclosure is to provide a transfer device and a transfer method of a light emitting diode and a method for manufacturing a display device using the same that reduce or minimize distortion of the plurality of LEDs during the detachment of a wafer and a donor or the donor and a display panel.

Technical benefits of the present disclosure are not limited to the above-mentioned benefits, and other benefits, which are not mentioned above, can be clearly understood by those skilled in the art from the following descriptions.

According to an aspect of the present disclosure, a transfer method of a light emitting diode includes bonding a wafer in which a plurality of light emitting diodes is formed and a donor, transferring the plurality of light emitting diodes to the donor, and detaching the wafer and the donor, the detaching of the wafer and the donor includes loading the bonded wafer and donor on a stage and a support member, fixing one of outermost portions of the donor by a fixing member, fixing one surface of the wafer to a head, moving the stage and the fixing member to a Z-axis direction, and moving the wafer and the head to an X-axis direction. Accordingly, the wafer and the donor are detached by the linear separation method to reduce the defective transfer of the plurality of light emitting diodes.

According to an aspect of the present disclosure, a method of manufacturing a display device includes bonding a wafer and a donor, transferring a plurality of light emitting diodes of a wafer to a donor, detaching the wafer and the donor, bonding the donor on which the plurality of light emitting diodes is disposed and the display panel, transferring the plurality of light emitting diodes of the donor to the display panel, and detaching the display panel and the donor, and the detaching of the wafer and the donor includes loading the bonded wafer and donor on a stage, fixing one of outermost portions of the donor by a fixing member, fixing one surface of the wafer to a head, moving the stage and the fixing member to a Z-axis direction, and moving the wafer and the head to an X-axis direction. Accordingly, during the detachment of the wafer and the donor, the wafer moves to the X-axis direction to relieve the tensile stress of the donor so that a shock to be applied to the plurality of light emitting diodes on a donor may be reduced or minimized.

According to an aspect of the present disclosure, a transfer device of a light emitting diode includes a stage on which a wafer and a donor are loaded, a head configured to fix one surface of the wafer, a fixing member configured to fix one side of the outermost portions of the donor to the stage and a support member configured to be disposed in a groove of the stage to support the donor. Accordingly, the wafer and the donor are detached by the linear separation method to reduce or minimize distortion of the plurality of light emitting diodes.

Other detailed matters of the exemplary embodiments are included in the detailed description and the drawings.

According to the present disclosure, when the donor is detached from the wafer, one end of the donor is physically fixed and the other end of the donor is supported to reduce or minimize the distortion of the plurality of LEDs on the donor.

According to the present disclosure, the donor and the wafer are linearly separated to reduce or minimize the degradation of a transfer yield of the plurality of LEDs.

According to the present disclosure, when the donor is detached from the wafer, the wafer moves to the X-axis direction to relieve a tensile stress of the donor generated during the detachment process.

According to the present disclosure, a surface separation phenomenon of the donor and the wafer in the latter part of the detachment process may be reduced or minimized.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary embodiment of the present disclosure;

FIG. 2A is a partial cross-sectional view of a display device according to an exemplary embodiment of the present disclosure;

FIG. 2B is a perspective view of a tiling display device according to an exemplary embodiment of the present disclosure;

FIG. 3 is a plan view of a display panel of a display device according to an exemplary embodiment of the present disclosure;

FIGS. 4A and 4B are plan views illustrating a pixel area of a display device according to an exemplary embodiment of the present disclosure;

FIG. 5 is a cross-sectional view of a display device according to an exemplary embodiment of the present disclosure;

FIG. 6 is a process flowchart for explaining a manufacturing method of a display device according to an exemplary embodiment of the present disclosure;

FIGS. 7A to 7G are schematic process diagrams for explaining a transfer device and a transfer method of a light emitting diode and a method for manufacturing a display device using the same, according to an exemplary embodiment of the present disclosure;

FIGS. 8A and 8B are schematic cross-sectional views for explaining a transfer device and a transfer method of a light emitting diode according to another exemplary embodiment of the present disclosure;

FIGS. 9A and 9B are schematic cross-sectional views for explaining a transfer device and a transfer method of a light emitting diode according to still another exemplary embodiment of the present disclosure;

FIGS. 10A and 10B are schematic cross-sectional views for explaining a transfer device and a transfer method of a light emitting diode according to still another exemplary embodiment of the present disclosure;

FIGS. 11A and 11B are schematic cross-sectional views for explaining a transfer device and a transfer method of a light emitting diode according to still another exemplary embodiment of the present disclosure; and

FIG. 12 is a schematic plan view of a stage for explaining a transfer device and a transfer method of a light emitting diode according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers, and the like illustrated in the accompanying drawings for describing the exemplary embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

Hereinafter, an LED transfer device, an LED transfer method, and a method for manufacturing a display device using the same according to exemplary embodiments of the present disclosure will be described in detail with reference to accompanying drawings.

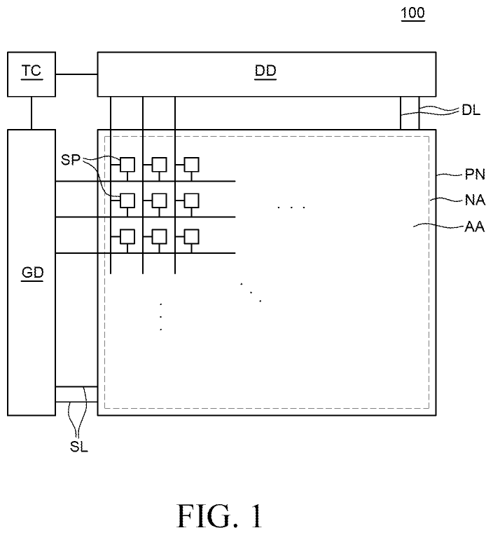

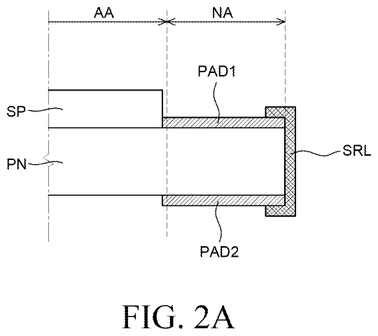

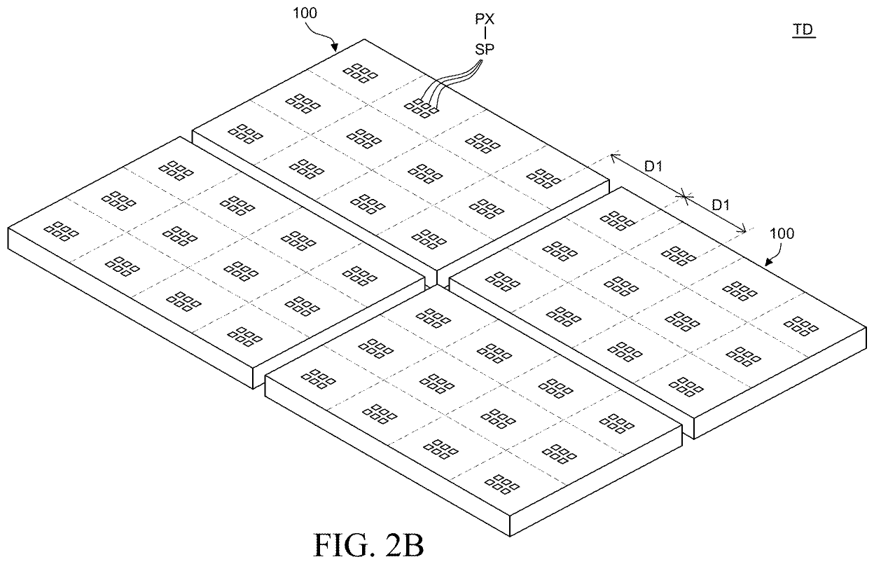

FIG. 1 is a schematic diagram of a display device according to an exemplary embodiment of the present disclosure. FIG. 2A is a partial cross-sectional view of a display device according to an exemplary embodiment of the present disclosure. FIG. 2B is a perspective view of a tiling display device according to an exemplary embodiment of the present disclosure. In FIG. 1, for the convenience of description, among various components of the display device 100, only a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP is connected to the scan lines SL and the data lines DL, respectively. In addition, even though it is not illustrated in the drawing, each of the plurality of sub pixels SP may be connected to a high potential power line, a low potential power line, a reference line, and the like.

In the display panel PN, an active area AA and a non-active area NA enclosing the active area AA may be defined.

The active area AA is an area in which images are displayed in the display device 100. In the active area AA, a plurality of sub pixels SP which configures a plurality of pixels PX and a circuit for driving the plurality of sub pixels SP may be disposed. The plurality of sub pixels SP is a minimum unit which configures the active area AA and n sub pixels SP may form one pixel. In each of the plurality of sub pixels SP, a light emitting diode, a thin film transistor for driving the light emitting diode, and the like may be disposed. The plurality of light emitting diodes may be defined in different manners depending on the type of the display panel PN. For example, when the display panel PN is an inorganic light emitting display panel, the light emitting diode may be a light emitting diode (LED) or a micro light emitting diode (LED).

In the active area AA, a plurality of wiring lines which transmits various signals to the plurality of sub pixels SP is disposed. For example, the plurality of wiring lines may include a plurality of data lines DL which supplies a data voltage to each of the plurality of sub pixels SP, a plurality of scan lines SL which supplies a scan signal to each of the plurality of sub pixels SP, and the like. The plurality of scan lines SL extends in one direction in the active area AA to be connected to the plurality of sub pixels SP and the plurality of data lines DL extends in a direction different from the one direction in the active area AA to be connected to the plurality of sub pixels SP. In addition, in the active area AA, a low potential power line, a high potential power line, and the like may be further disposed, but are not limited thereto.

The non-active area NA is an area where images are not displayed so that the non-active area NA may be defined as an area extending from the active area AA. In the non-active area NA, a link line which transmits a signal to the sub pixel SP of the active area AA, a pad electrode, a driving IC, such as a gate driver IC or a data driver IC, or the like may be disposed.

In the meantime, the non-active area NA may be located on a rear surface of the display panel PN, that is, a surface on which the sub pixels SP are not disposed or may be omitted, and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner. For example, the data driver DD and the timing controller TC are formed in separate flexible film and printed circuit board PCB. The data driver DD and the timing controller TC may be electrically connected to the display panel PN by bonding the flexible film and the printed circuit board PCB to the pad electrode formed in the non-active area NA of the display panel PN.

If the gate driver GD is mounted in the GIP manner and the data driver DD and the timing controller TC transmit a signal to the display panel PN through a pad electrode of the non-active area NA, an area of the non-active area NA for disposing the gate driver GD and the pad electrode is necessary more than a predetermined level. Accordingly, a bezel may be increased.

In contrast, when the gate driver GD is mounted in the active area AA in the GIA manner and a side line which connects the signal line on the front surface of the display panel PN to the pad electrode on a rear surface of the display panel PN is formed to bond the flexible film and the printed circuit board onto a rear surface of the display panel PN, the non-active area NA may be reduce or minimized on the front surface of the display panel PN. That is, when the gate driver GD, the data driver DD, and the timing controller TC are connected to the display panel PN as described above, a zero bezel with substantially no bezel may be implemented.

Specifically, referring to FIGS. 2A and 2B, in the non-active area NA of the display panel PN, a plurality of pad electrodes PAD1 and PAD2 for transmitting various signals to the plurality of sub pixels SP is disposed. For example, in the non-active area NA on the front surface of the display panel PN, a plurality of first pad electrodes PAD1 which transmits a signal to the plurality of sub pixels SP is disposed. In the non-active area NA on the rear surface of the display panel PN, a plurality of second pad electrodes PAD2 which are electrically connected to a driving component, such as a flexible film and the printed circuit board, is disposed. That is, on the front surface of the display panel PN on which images are displayed, only a pad area of the non-active area NA in which the first pad electrode PAD1 is disposed may be formed at minimum.

In this case, even though it is not illustrated in the drawing, various signal lines connected to the plurality of sub pixels SP, for example, a scan line SL or a data line DL extends from the active area AA to the non-active area NA to be electrically connected to the first pad electrode PAD1.

The side line SRL is disposed along a side surface of the display panel PN. The side line SRL may electrically connect the first pad electrode PAD1 on the front surface of the display panel PN and the second pad electrode PAD2 on the rear surface of the display panel PN. Therefore, a signal from a driving component on the rear surface of the display panel PN may be transmitted to the plurality of sub pixels SP through the second pad electrode PAD2, the side line SRL, and the first pad electrode PAD1. Accordingly, a signal transmitting path from the front surface of the display panel PN to the side surface and the rear surface thereof is formed to reduce or minimize an area of the non-active area NA on the front surface of the display panel PN.

Referring to FIG. 2B, a tiling display device TD having a large screen size may be implemented by connecting a plurality of display devices 100. At this time, as illustrated in FIG. 2A, when the tiling display device TD is implemented using a display device 100 with a reduce or minimized bezel, a scam area in which an image between the display devices TD is not displayed is reduce or minimized so that a display quality may be improved.

For example, the plurality of sub pixels SP may form one pixel PX and a distance D1 between an outermost pixel PX of one display device 100 and an outermost pixel PX of another display device 100 adjacent to one display device may be implemented to be equal to a distance D1 between pixels PX in one display device 100. Accordingly, a distance D1 between pixels PX between the display devices 100 is constantly configured to reduce or minimize the seam area.

However, FIGS. 2A and 2B are illustrative so that the display device according to the exemplary embodiment of the present disclosure may be a general display device with a bezel, but is not limited thereto.

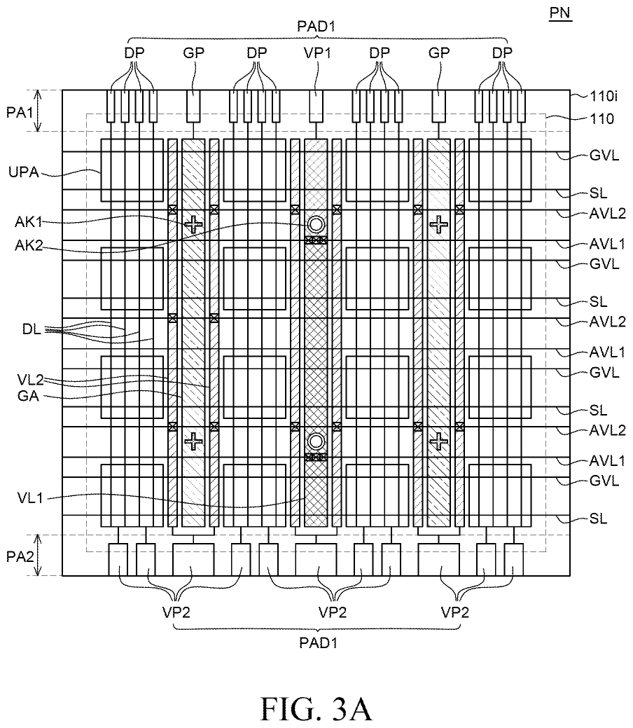

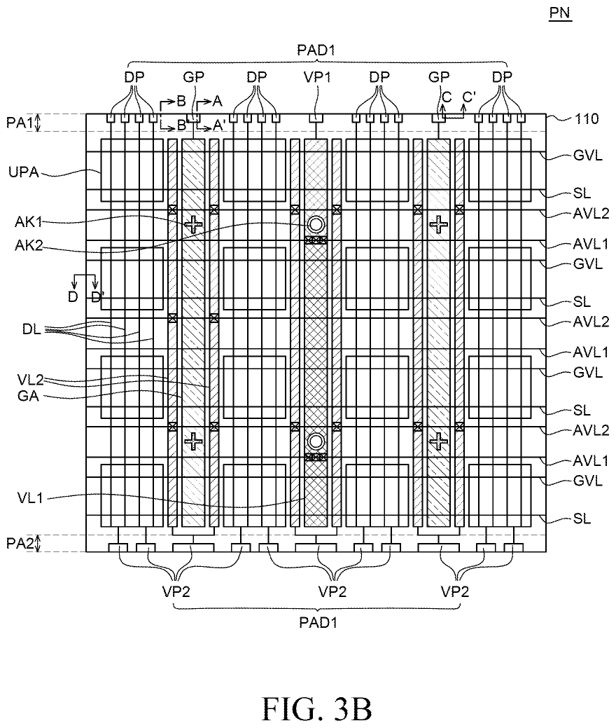

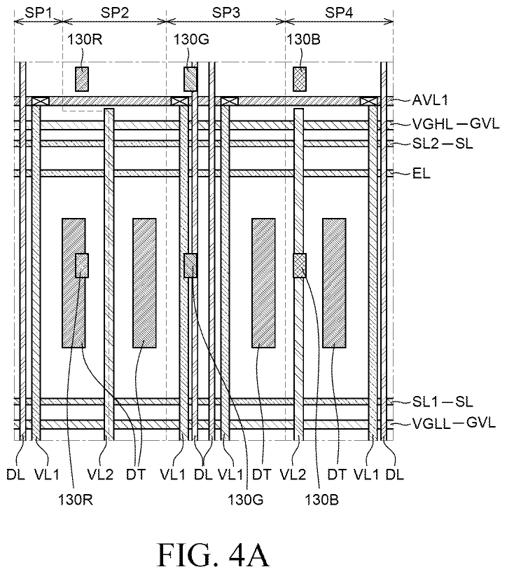

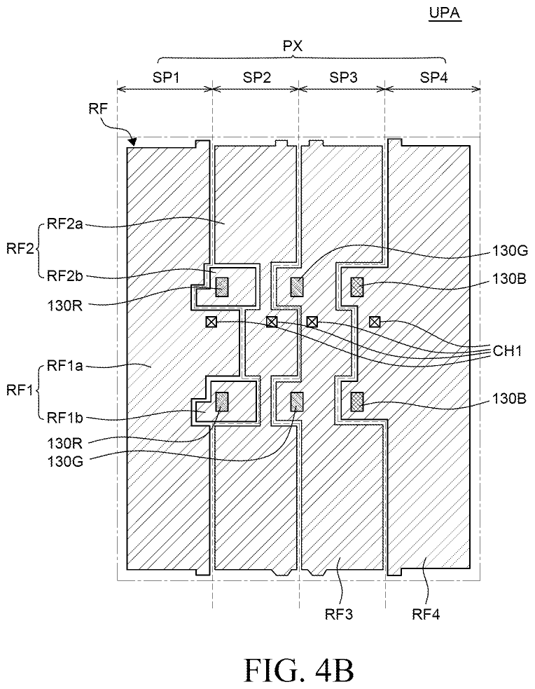

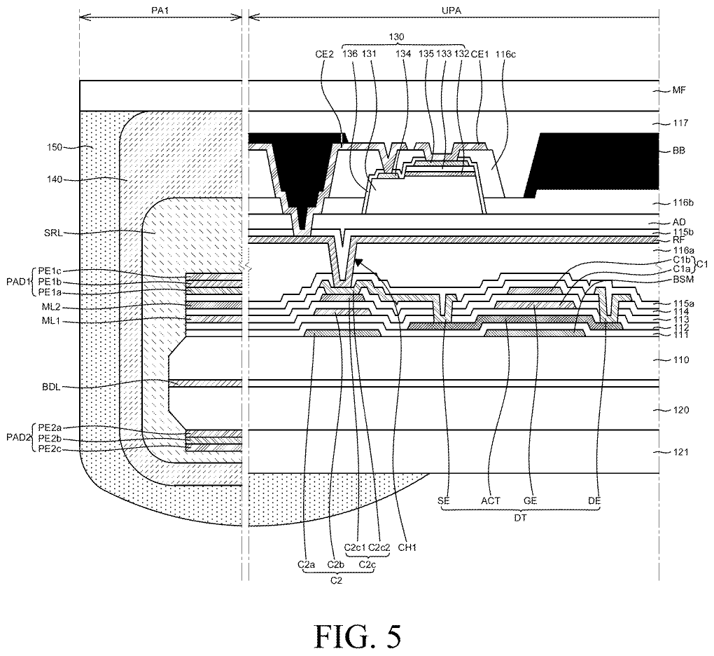

FIG. 3 is a plan view of a display panel of a display device according to an exemplary embodiment of the present disclosure. FIGS. 4A and 4B are plan views illustrating a pixel area of a display device according to an exemplary embodiment of the present disclosure. FIG. 5 is a cross-sectional view of a display device according to an exemplary embodiment of the present disclosure. For the convenience of description, in FIG. 4A, only the plurality of light emitting diodes 130, a driving transistor DT of the pixel circuit, and a plurality of wiring lines are illustrated and in FIG. 4B, only a plurality of reflection plates RF and a plurality of light emitting diodes 130 are illustrated.

First, referring to FIGS. 3 to 5, the display panel PN includes a first substrate 110. The first substrate 110 is a substrate which supports components disposed above the display device 100 and may be an insulating substrate. A plurality of pixels PX is formed on the first substrate 110 to display images. For example, the first substrate 110 may be formed of glass or resin. Further, the first substrate 110 may include polymer or plastic. In some exemplary embodiments, the first substrate 110 may be formed of a plastic material having flexibility.

Referring to FIG. 3, in the first substrate 110, a plurality of pixel areas UPA, a plurality of gate driving areas GA, and a plurality of pad areas are disposed. Among them, the plurality of pixel areas UPA and the plurality of gate driving areas GA may be included in the active area AA of the display panel PN.

First, the plurality of pixel areas UPA is areas in which the plurality of pixels PX is disposed. The plurality of pixel areas UPA may be disposed by forming a plurality of rows and a plurality of columns. Each of the plurality of pixels PX disposed in the plurality of pixel areas UPA includes a plurality of sub pixels SP. Each of the plurality of sub pixels SP includes a light emitting diode 130 and a pixel circuit to independently emit light.

The plurality of gate driving areas GA is areas where gate drivers GD are disposed. The gate driver GD may be mounted in the active area AA in a gate in active area (GIA) manner. For example, the gate driving area GA may be formed along a row direction and/or column direction between the plurality of pixel areas UPA. The gate driver GD formed in the gate driving area GA may supply the scan signal to the plurality of scan lines SL.

The gate driver GD disposed in the gate driving area GA may include a circuit for outputting a scan signal. For example, the gate driver may include a plurality of gate driving transistors and/or capacitors, like the pixel circuit. Here, active layers of the plurality of gate driving transistors may be formed of a semiconductor material, such as an oxide semiconductor, amorphous silicon, or polysilicon, but are not limited thereto. The active layers of the plurality of gate driving transistors may be formed of the same material or different materials from each other. Further, the active layers of the plurality of gate driving transistors of the gate driver may be formed of the same material as active layers of various transistors of the pixel circuit or formed of different materials from each other.

The plurality of pad areas is areas in which a plurality of first pad electrodes PAD1 is disposed. The plurality of first pad electrodes PAD1 may transmit various signals to various wiring lines extending in a column direction in the active area AA. For example, the plurality of first pad electrodes PAD1 includes a data pad DP, a gate pad GP, a high potential power pad VP1, and a low potential power pad VP2. The data pad DP transmits a data voltage to the data line DL and the gate pad GP transmits a clock signal, a start signal, a gate low voltage, a gate high voltage, and the like for driving the gate driver GD to the gate driver GD. The high potential power pad VP1 transmits a high potential power voltage to the high potential power line VL1 and the low potential power pad VP2 transmits a low potential power voltage to the low potential power line VL2.

The plurality of pad areas includes a first pad area PA1 located at an upper edge of the display panel PN and a second pad area PA2 of the display panel PN. At this time, in the first pad area PA1 and the second pad area PA2, different types of first pad electrodes PAD1 are disposed. For example, in the first pad area PA1, among the plurality of first pad electrodes PAD1, the data pad DP, the gate pad GP, and the high potential power pad VP1 may be disposed and in the second pad area PA2, the low potential power pad VP2 may be disposed.

At this time, the plurality of first pad electrodes PAD1 may be formed to have different sizes, respectively. For example, the plurality of data pads DP which is connected to the plurality of data lines DL one to one may have a smaller width and the high potential power pad VP1, the low potential power pad VP2, and the gate pad GP may have a larger width. However, widths of the data pad DP, the gate pad GP, the high potential power pad VP1, and the low potential power pad VP2 illustrated in FIG. 3 are illustrative so that the first pad electrode PAD1 may be configured in various sizes, but is not limited thereto.

In the meantime, in order to reduce the bezel of the display panel PN, an edge of the display panel PN may be cut to be removed. The plurality of pixels PX, the plurality of wiring lines, and the plurality of first pad electrodes PAD1 are formed on an initial first substrate 110i and an edge part of the initial first substrate 110i is ground to reduce the bezel area. During the grinding process, a part of the initial first substrate 110i is removed to form a first substrate 110 with a smaller size. At this time, parts of the plurality of first pad electrodes PAD1 and wiring lines disposed at the edge of the first substrate 110 may be removed. Accordingly, only a part of the plurality of first pad electrodes PAD1 may remain on the first substrate 110.

Next, the plurality of data lines DL which extends in a column direction from the plurality of first pad electrodes PAD1 is disposed on the first substrate 110 of the display panel PN. The plurality of data lines DL may extend from the plurality of data pads DP of the first pad area PA1 toward the plurality of pixel areas UPA. The plurality of data lines DL extends in a column direction and overlaps the plurality of pixel areas UPA. Therefore, the plurality of data lines DL may transmit the data voltage to the pixel circuit of each of the plurality of sub pixels SP.

The plurality of high potential power lines VL1 extending in the column direction is disposed on the first substrate 110 of the display panel PN. Some of the plurality of high potential power lines VL1 extends from the high potential power pad VP1 of the first pad area PA1 to the plurality of pixel areas UPA to transmit the high potential power voltage to the light emitting diode 130 of each of the plurality of sub pixels SP. The others of the plurality of high potential power lines VL1 may be electrically connected to the other high potential power line VL1 by means of an auxiliary high potential power line AVL1 to be described below. In FIG. 3, for the convenience of description, even though it is illustrated that one high potential power line VL1 and one high potential power pad VP1 are disposed, a plurality of high potential power lines VL1 and high potential power pads VP1 may be disposed.

The plurality of low potential power lines VL2 extending in the column direction is disposed on the first substrate 110 of the display panel PN. At least some of the plurality of low potential power lines VL2 extends from the low potential power pad VP2 of the second pad area PA2 to the plurality of pixel areas UPA to transmit the low potential power voltage to the pixel circuit of each of the plurality of sub pixels SP. The others of the plurality of low potential power lines VL2 may be electrically connected to the other low potential power line VL2 by means of an auxiliary low potential power line AVL2 to be described below.

The plurality of scan lines SL extending in the row direction is disposed on the first substrate 110 of the display panel PN. The plurality of scan lines SL extends in the row direction and may be disposed across the plurality of pixel areas UPA and the plurality of gate driving areas GA. The plurality of scan lines SL may transmit the scan signal from the gate driver GD to the pixel circuits of the plurality of sub pixels SP.

A plurality of auxiliary high potential power lines AVL1 extending in the row direction is disposed on the first substrate 110 of the display panel PN. The plurality of auxiliary high potential power lines AVL1 may be disposed in an area between the plurality of pixel areas UPA. The plurality of auxiliary high potential power lines AVL1 extending in the row direction is electrically connected to the plurality of high potential power lines VL1 extending in the column direction through a contact hole and may form a mesh structure. Therefore, the plurality of auxiliary high potential power lines AVL1 and the plurality of high potential power lines VL1 are configured to form a mesh structure to reduce or minimize voltage drop and voltage deviation.

A plurality of auxiliary low potential power lines AVL2 extending in the row direction is disposed on the first substrate 110 of the display panel PN. The plurality of auxiliary low potential power lines AVL2 may be disposed in an area between the plurality of pixel areas UPA. The plurality of auxiliary low potential power lines AVL2 extending in the row direction is electrically connected to the plurality of low potential power lines VL2 extending in the column direction through a contact hole to form a mesh structure. Therefore, the plurality of auxiliary low potential power lines AVL2 and the plurality of low potential power lines VL2 are configured to form a mesh structure to reduce a resistance of the wiring line and reduce or minimize voltage deviation.

Referring to FIGS. 3 and 4A, the plurality of gate driving lines GVL extending in the row direction and the column direction is disposed on the first substrate 110 of the display panel PN. Some of the plurality of gate driving lines GVL extends from the gate pad GP of the first pad area PA1 to the gate driving area GA to transmit a signal to the gate driver GD. The others of the plurality of gate driving lines GVL extend in the row direction and may transmit the signal to the gate drivers GD of the plurality of gate driving areas GA. Therefore, various signals are transmitted from the gate driving line GVL to the gate driver GD to drive the gate driver GD.

The plurality of gate driving lines GVL may include wiring lines which transmit a clock signal, a start signal, a gate high voltage, a gate low voltage, and the like to the gate driver GD. Therefore, various signals are transmitted from the gate driving line GVL to the gate driver GD to drive the gate driver GD.

For example, referring to FIG. 4A, the plurality of gate driving lines GVL may include a gate power line which transmits a power voltage to the gate driver GD of the gate driving area GA. The plurality of gate power lines includes a first gate power line VGHL which transmits a gate high voltage to the gate driver GD and a second gate power line VGLL which transmits a gate low voltage to the gate driver GD.

A plurality of alignment keys is disposed in an area between the plurality of pixel areas UPA in the display panel PN. The plurality of alignment keys is used for alignment during the manufacturing process of the display panel PN. The plurality of alignment keys includes a first alignment key AK1 and a second alignment key AK2.

The first alignment key AK1 may be disposed in the gate driving area GA between the plurality of pixel areas UPA. The first alignment key AK1 may be used to inspect an alignment position of the plurality of light emitting diodes 130. For example, the first alignment key AK1 may have a cross shape, but is not limited thereto.

The second alignment key AK2 may be disposed to overlap the high potential power line VL1 between the plurality of pixel areas UPA. In the high potential power line VL1, a hole overlapping the second alignment key AK2 is formed to divide the second alignment key AK2 and the high potential power line VL1. The second alignment key AK2 may be used to align the display panel PN and a donor. The display panel PN and the donor are aligned using the second alignment key AK2 and the plurality of light emitting diodes 130 of the donor may be transferred onto the display panel PN. For example, the second alignment key AK2 may have a circular ring shape, but is not limited thereto.

Hereinafter, the plurality of sub pixels SP of the pixel area UPA will be described in more detail with reference to FIGS. 4A to 5.

Referring to FIGS. 4A and 4B, in one pixel area UPA, a plurality of sub pixels SP which forms one pixel PX is disposed. For example, the plurality of sub pixels SP may include a first sub pixel SP1, a second sub pixel SP2, a third sub pixel SP3, and a fourth sub pixel SP4 which emit different color light. For example, the first sub pixel SP1 and the second sub pixel SP2 are red sub pixels, the third sub pixel SP3 is a green sub pixel, and the fourth sub pixel SP4 is a blue sub pixel, but they are not limited thereto.

Hereinafter, the description will be made by assuming that one pixel PX includes one first sub pixel SP1, one second sub pixel SP2, one third sub pixel SP3, and one fourth sub pixel SP4, that is, two red sub pixels, one green sub pixel, and one blue sub pixel. However, the configuration of the pixel PX is not limited thereto.

Referring to FIG. 4A, as described above, a plurality of wiring lines which supplies various signals to the plurality of sub pixels SP is disposed in the plurality of pixel areas UPA of the first substrate 110. For example, the plurality of data lines DL, the plurality of high potential power lines VL1, and the plurality of low potential power lines VL2 extending in the column direction may be disposed on the first substrate 110. For example, the plurality of emission control signal lines EL, the plurality of auxiliary high potential power lines AVL1, the plurality of auxiliary low potential power lines AVL2, the plurality of first scan lines SL1, and the plurality of second scan lines SL2 extending in the row direction may be disposed on the first substrate 110. The high potential power line VL1 extending in the column direction may be electrically connected to the auxiliary high potential power line AVL1 extending in the row direction through a contact hole. At this time, the emission control signal line EL transmits an emission control signal to the pixel circuits of the plurality of sub pixels SP to control emission timings of the plurality of sub pixels SP, respectively.

Some gate driving lines GVL which transmit signals to the plurality of gate drivers GD, respectively, disposed to be spaced apart from each other with the pixel area UPA therebetween may be disposed across the pixel area UPA while extending to the row direction. For example, a first gate power line VGHL which supplies a gate high voltage to the gate driver GD and a second gate power line VGLL which supplies a gate low voltage may be disposed across the pixel area UPA.

In the meantime, even though it is illustrated that the plurality of scan lines SL includes a first scan line SL1 and a second scan line SL2, the configuration of the plurality of scan lines SL may vary depending on the pixel circuit configuration of the sub pixel SP, but is not limited thereto.

The pixel circuit for driving the light emitting diode 130 is disposed in each of the plurality of sub pixels SP on the first substrate 110. The pixel circuit may include a plurality of thin film transistors and a plurality of capacitors. In FIGS. 4A and 5, for the convenience of description, only a driving transistor DT, a first capacitor C1, and a second capacitor C2, among configurations of the pixel circuit, are illustrated. However, the pixel circuit may further include a switching transistor, a sensing transistor, an emission control transistor, and the like, but is not limited thereto.

First, a light shielding layer BSM is disposed on the first substrate 110. The light shielding layer BSM blocks light which is incident onto an active layer ACT of the plurality of transistors to reduce or minimize a leakage current. For example, the light shielding layer BSM is disposed below the active layer ACT of the driving transistor DT to block light incident onto the active layer ACT. If light is irradiated onto the active layer ACT, a leakage current is generated, which deteriorates the reliability of the transistor. Accordingly, the light shielding layer BSM which blocks the light is disposed on the first substrate 110 to improve the reliability of the driving transistor DT. The light shielding layer BSM may be configured by an opaque conductive material such as copper (Cu), aluminum (Al), molybdenum (Mo), nickel (Ni), titanium (Ti), chrome (Cr), or an alloy thereof, but is not limited thereto.

A buffer layer 111 is disposed on the light shielding layer BSM. The buffer layer 111 may reduce permeation of moisture or impurities through the first substrate 110. The buffer layer 111 may be configured by a single layer or a double layer of silicon oxide SiOₓ or silicon nitride SiNₓ, but is not limited thereto. However, the buffer layer 111 may be omitted depending on a type of the first substrate 110 or a type of the thin film transistor, but is not limited thereto.

A driving transistor DT including an active layer ACT, a gate electrode GE, a source electrode SE, and a drain electrode DE is disposed on the buffer layer 111.

First, the active layer ACT of the driving transistor DT is disposed on the buffer layer 111. The active layer ACT may be formed of a semiconductor material such as an oxide semiconductor, amorphous silicon, or polysilicon, but is not limited thereto. Further, even though it is not illustrated in the drawings, other transistors, such as a switching transistor, a sensing transistor, and an emission control transistor, other than the driving transistor DT, may be further disposed on the buffer layer 111. The active layers of the transistors may be also formed of a semiconductor material, such as an oxide semiconductor, amorphous silicon, or polysilicon, but are not limited thereto. The active layer of the transistor included in the pixel circuit, such as the driving transistor DT, the switching transistor, the sensing transistor, and the emission control signal, may be formed of the same material, or formed of different materials from each other.

A gate insulating layer 112 is disposed on the active layer ACT. The gate insulating layer 112 is an insulating layer which electrically insulates the active layer ACT from the gate electrode GE and may be configured by a single layer or a double layer of silicon oxide SiOₓ or silicon nitride SiNₓ, but is not limited thereto.

The gate electrode GE is disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

A first interlayer insulating layer 113 and a second interlayer insulating layer 114 are disposed on the gate electrode GE. In the first interlayer insulating layer 113 and the second interlayer insulating layer 114, contact holes through which each of the source electrode SE and the drain electrode DE is connected to the active layer ACT are formed. The first interlayer insulating layer 113 and the second interlayer insulating layer 114 are insulating layers which protect components therebelow and may be configured by single layers or double layers of silicon oxide SiOₓ or silicon nitride SiNₓ, but are not limited thereto.

The source electrode SE and the drain electrode DE which are electrically connected to the active layer ACT are disposed on the second interlayer insulating layer 114. The source electrode SE is connected to the second capacitor C2 and the first electrode 134 of the light emitting diode 130 and the drain electrode DE is connected to the other configuration of the pixel circuit. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

Next, the first capacitor C1 is disposed on the gate insulating layer 112. The first capacitor C1 includes a 1-1-th capacitor electrode C1a and a 1-2-th capacitor electrode C1b.

First, the 1-1-th capacitor electrode C1a is disposed on the gate insulating layer 112. The 1-1-th capacitor electrode C1a may be integrally formed with the gate electrode GE of the driving transistor DT.

The 1-2-th capacitor electrode C1b is disposed on the first interlayer insulating layer 113. The 1-2-th capacitor electrode C1b is disposed to overlap the 1-1-th capacitor electrode C1a with the first interlayer insulating layer 113 therebetween.

Therefore, the first capacitor C1 is connected to the gate electrode GE of the driving transistor DT to maintain a voltage of the gate electrode GE of the driving transistor DT for a predetermined period.

Next, the second capacitor C2 is disposed on the first substrate 110. The second capacitor C2 includes a 2-1-th capacitor electrode C2a, a 2-2-th capacitor electrode C2b, and a 2-3-th capacitor electrode C2c. The second capacitor C2 includes the 2-1-th capacitor electrode C2a which is a lower capacitor electrode, the 2-2-th capacitor electrode C2b which is an intermediate capacitor electrode, and the 2-3-th capacitor electrode C2c which is an upper capacitor electrode.

The 2-1-th capacitor electrode C2a is disposed on the first substrate 110. The 2-1-th capacitor electrode C2a may be disposed on the same layer as the light shielding layer BSM and may be formed of the same material.

The 2-2-th capacitor electrode C2b is disposed on the buffer layer 111 and the gate insulating layer 112. The 2-2-th capacitor electrode C2b may be disposed on the same layer as the gate electrode GE and may be formed of the same material.

The 2-3-th capacitor electrode C2c is disposed on the first interlayer insulating layer 113. The 2-3-th capacitor electrode C2c may be configured by a first layer C2cl and a second layer C2c2. The first layer C2cl of the 2-3-th capacitor electrode C2c may be formed on the same layer as the 1-2-th capacitor electrode C1b with the same material. The first layer C2cl may be disposed to overlap the 2-1-th capacitor electrode C2a and the 2-2-th capacitor electrode C2b with the first interlayer insulating layer 113 therebetween.

The second layer C2c2 of the 2-3-th capacitor electrode C2c is disposed on the second interlayer insulating layer 114. The second layer C2c2 is a part extending from the source electrode SE of the driving transistor DT and may be connected to the first layer C2cl through the contact hole of the second interlayer insulating layer 114.

Accordingly, the second capacitor C2 is electrically connected between the source electrode SE of the driving transistor DT and the light emitting diode 130 to increase capacitance inherent in the light emitting diode 130 and allow the light emitting diode 130 to emit light with a higher luminance.

A first passivation layer 115a is disposed on the driving transistor DT, the first capacitor C1, and the second capacitor C2. The first passivation layer 115a is an insulating layer which protects components below the first passivation layer 115a and may be configured by an inorganic material, such as silicon oxide SiOₓ or silicon nitride SiNₓ, but is not limited thereto.

A first planarization layer 116a is disposed on the first passivation layer 115a. The first planarization layer 116a may planarize an upper portion of the pixel circuit including the driving transistor DT. The first planarization layer 116a may be configured by a single layer or a double layer, and for example, configured by benzocyclobutene or an acrylic organic material, but is not limited thereto.

Referring to FIGS. 4B and 5 together, a plurality of reflection plates RF is disposed on the first planarization layer 116a. The reflection plate RF is a configuration which reflects light emitted from the plurality of light emitting diodes 130 above the first substrate 110 and may be formed with a shape corresponding to each of the plurality of sub pixels SP. One reflection plate RF may be disposed to cover the most area of one sub pixel SP. The reflection plate RF may reflect the light emitted from the light emitting diode 130 and may be also used as an electrode which electrically connects the light emitting diode 130 and the pixel circuit. Therefore, the reflection plate RF may include various conductive layers in consideration of a light reflection efficiency and a resistance. For example, the reflection plate RF may use an opaque conductive layer such as silver (Ag), aluminum (Al), molybdenum (Mo), titanium (Ti), or an alloy thereof and a transparent conductive layer such as indium tin oxide, but the structure of the reflection plate RF is not limited thereto.

The reflection plate RF includes a first reflection plate RF1 corresponding to the first sub pixel SP1, a second reflection plate RF2 corresponding to the second sub pixel SP2, a third reflection plate RF3 corresponding to the third sub pixel SP3, and a fourth reflection plate RF4 corresponding to the fourth sub pixel SP4.

The first reflection plate RF1 includes a 1-1-th reflection plate RF1a overlapping most of the first sub pixel SP1 and a 1-2-th reflection plate RF1b overlapping the red light emitting diode 130R of the first sub pixel SP1. The 1-1-th reflection plate RF1a may reflect light emitted from the red light emitting diode 130R above the red light emitting diode 130R. The 1-1-th reflection plate RF1a may be electrically connected to the source electrode SE of the driving transistor DT and the second capacitor C2 through a first contact hole CHI of the first planarization layer 116a and the first passivation layer 115a. Therefore, the 1-1-th reflection plate RF1a may electrically connect the driving transistor DT and the first electrode 134 of the red light emitting diode 130R. The 1-2-th reflection plate RF1b may reflect light emitted from the red light emitting diode 130R above the red light emitting diode 130R. The 1-2-th reflection plate RF1b may serve as an electrode which electrically connects the second electrode 135 of the red light emitting diode 130R and the high potential power line VL1.

The second reflection plate RF2 includes a 2-1-th reflection plate RF2a overlapping most of the second sub pixel SP2 and a 2-2-th reflection plate RF2b overlapping the red light emitting diode 130R of the second sub pixel SP2. The 2-1-th reflection plate RF2a may reflect light emitted from the red light emitting diode 130R above the red light emitting diode 130R. The 2-1-th reflection plate RF2a is electrically connected to the source electrode SE of the driving transistor DT and the second capacitor C2 through the first contact hole CHI to transmit a driving current from the driving transistor DT to the first electrode 134 of the red light emitting diode 130R. The 2-2-th reflection plate RF2b may be used as an electrode which reflects the light emitted from the red light emitting diode 130R above the red light emitting diode 130R and electrically connects the second electrode 135 of the red light emitting diode 130R to the high potential power line VL1.

The third reflection plate RF3 may be formed as one third reflection plate RF3 which overlaps the entire third sub pixel SP3. The third reflection plate RF3 may reflect light emitted from the green light emitting diode 130G of the third sub pixel SP3 above the green light emitting diode 130G. The third reflection plate RF3 is electrically connected to the source electrode SE of the driving transistor DT and the second capacitor C2 through the first contact hole CHI to transmit a driving current from the driving transistor DT to the first electrode 134 of the green light emitting diode 130G.

The fourth reflection plate RF4 may be formed as one fourth reflection plate RF4 which overlaps the entire fourth sub pixel SP4. The fourth reflection plate RF4 may reflect light emitted from the blue light emitting diode 130B of the fourth sub pixel SP4 above the blue light emitting diode 130B. The fourth reflection plate RF4 is electrically connected to the source electrode SE of the driving transistor DT and the second capacitor C2 through the first contact hole CHI to transmit a driving current from the driving transistor DT to the first electrode 134 of the blue light emitting diode 130B.

In the meantime, even though it has been described that the first sub pixel SP1 and the second sub pixel SP2 are formed with two reflection plates RF and the third sub pixel SP3 and the fourth sub pixel SP4 are formed with one reflection plate RF, the reflection plate RF may be designed in various manners. For example, only one reflection plate RF may be disposed in all the plurality of sub pixels SP, like the third sub pixel SP3 and the fourth sub pixel SP4 or a plurality of reflection plates RF may be disposed in all the sub pixels, like the first sub pixel SP1 and the second sub pixel SP2, but the reflection plate is not limited thereto.

Further, it has been described that the red light emitting diode 130R of each of the first sub pixel SP1 and the second sub pixel SP2 is electrically connected to the high potential power line VL1 through the 1-2-th reflection plate RF1b and the 2-2-th reflection plate RF2b. However, all the red light emitting diode 130R, the green light emitting diode 130G, and the blue light emitting diode 130B may be separately connected to the high potential power line VL1 without the reflection plate RF, but are not limited thereto.

Referring to FIG. 5, the second passivation layer 115b is disposed on the plurality of reflection plates RF. The second passivation layer 115b is an insulating layer which protects components below the second passivation layer 115b and may be configured by a single layer or a double layer of silicon oxide SiOₓ or silicon nitride SiNₓ, but is not limited thereto.

An adhesive layer AD is disposed on the second passivation layer 115b. The adhesive layer AD is formed on the entire surface of the first substrate 110 to fix the light emitting diode 130 disposed on the adhesive layer AD. The adhesive layer AD may be formed of a photo curable adhesive material which is cured by light. For example, the adhesive layer AD may be formed of an acrylic material including a photoresist, but is not limited thereto. The adhesive layer AD may be formed on the entire surface of the first substrate 110 excluding a pad area in which the first pad electrode PAD1 is disposed.

The plurality of light emitting diodes 130 is disposed in each of the plurality of sub pixels SP on the adhesive layer AD. The light emitting diode 130 is an element which emits light by a current and may include a red light emitting diode 130R which emits red light, a green light emitting diode 130G which emits green light, and a light emitting diode 130 which emits blue light and may implement light with various colors including white by a combination thereof. For example, the light emitting diode 130 may be a light emitting diode (LED) or a micro LED, but is not limited thereto.

One red light emitting diode 130R is disposed in each of the first sub pixel SP1 and the second sub pixel SP2, one pair of green light emitting diodes 130G is disposed in the third sub pixel SP3, and one pair of blue light emitting diodes 130B is disposed in the fourth sub pixel SP4. That is, two red light emitting diodes 130R, two green light emitting diodes 130G, and two blue light emitting diodes 130B may be disposed in one pixel PX. At this time, each of the red light emitting diodes 130R is connected to the driving transistor DT of each of the first sub pixel SP1 and the second sub pixel SP2 to be individually driven. In contrast, one pair of green light emitting diodes 130G of the third sub pixel SP3 and one pair of blue light emitting diodes 130B of the fourth sub pixel SP4 are connected to one driving transistor DT in parallel to be driven.

The plurality of light emitting diodes 130 includes a first semiconductor layer 131, an emission layer 132, a second semiconductor layer 133, a first electrode 134, and a second electrode 135.

The first semiconductor layer 131 is disposed on the adhesive layer AD and the second semiconductor layer 133 is disposed on the first semiconductor layer 131. The first semiconductor layer 131 and the second semiconductor layer 133 may be layers formed by doping n-type and p-type impurities into a specific material. For example, the first semiconductor layer 131 and the second semiconductor layer 133 may be layers doped with n-type and p-type impurities into a material such as gallium nitride GaN, indium aluminum phosphide InAIP, or gallium arsenide GaAs. The p-type impurity may be magnesium (Mg), zinc (Zn), beryllium (Be), and the like, and the n-type impurity may be silicon (Si), germanium, tin (Sn), and the like, but are not limited thereto.

The emission layer 132 is disposed between the first semiconductor layer 131 and the second semiconductor layer 133. The emission layer 132 is supplied with holes and electrons from the first semiconductor layer 131 and the second semiconductor layer 133 to emit light. The emission layer 132 may be formed by a single layer or a multi-quantum well (MQW) structure, and for example, may be formed of indium gallium nitride InGaN, gallium nitride GaN, or the like, but is not limited thereto.

The first electrode 134 is disposed on the first semiconductor layer 131. The first electrode 134 is an electrode which electrically connects the driving transistor DT and the first semiconductor layer 131. In this case, the first semiconductor layer 131 is a semiconductor layer doped with an n-type impurity and the first electrode 134 may be a cathode. The first electrode 134 may be disposed on a top surface of the first semiconductor layer 131 which is exposed from the emission layer 132 and the second semiconductor layer 133. The first electrode 134 may be configured by a conductive material, for example, a transparent conductive material, such as indium tin oxide ITO or indium zinc oxide IZO or an opaque conductive material, such as titanium (Ti), gold (Au), silver (Ag), copper (Cu) or an alloy thereof, but is not limited thereto.

The second electrode 135 is disposed on the second semiconductor layer 133. The second electrode 135 may be disposed on the top surface of the second semiconductor layer 133. The second electrode 135 is an electrode which electrically connects the high potential power line VL1 and the second semiconductor layer 133. In this case, the second semiconductor layer 133 is a semiconductor layer doped with a p-type impurity and the second electrode 135 may be an anode. The second electrode 135 may be configured by a transparent conductive material, such as indium tin oxide ITO or indium zinc oxide IZO or an opaque conductive material, such as titanium (Ti), gold (Au), silver (Ag), copper (Cu) or an alloy thereof, but is not limited thereto.

Next, an encapsulation film 136 which encloses the first semiconductor layer 131, the emission layer 132, the second semiconductor layer 133, the first electrode 134, and the second electrode 135 is disposed. The encapsulation film 136 is formed of an insulating material to protect the first semiconductor layer 131, the emission layer 132, and the second semiconductor layer 133. In the encapsulation film 136, a contact hole which exposes the first electrode 134 and the second electrode 135 is formed to electrically connect a first connection electrode CE1 and a second connection layer CE2 to the first electrode 134 and the second electrode 135.

In the meantime, a part of the side surface of the first semiconductor layer 131 may be exposed from the encapsulation film 136. The light emitting diode 130 manufactured on the wafer is separated from the wafer to be transferred onto the display panel PN. However, during the process of separating the light emitting diode 130 from the wafer, a part of the encapsulation film 136 may be torn. For example, a part of the encapsulation film 136 which is adjacent to a lower edge of the first semiconductor layer 131 of the light emitting diode 130 is torn during the process of separating the light emitting diode 130 from the wafer. Accordingly, a part of a lower side surface of the first semiconductor layer 131 may be exposed to the outside. However, even though the lower portion of the light emitting diode 130 is exposed from the encapsulation film 136, the first connection electrode CE1 and the second connection electrode CE2 are formed after forming the second planarization layer 116b and the third planarization layer 116c which cover the side surface of the first semiconductor layer 131. Accordingly, a short defect may be reduced.

Next, the second planarization layer 116b and the third planarization layer 116c are disposed on the adhesive layer AD and the light emitting diode 130.

The second planarization layer 116b overlaps a part of side surfaces of the plurality of light emitting diodes 130 to fix and protect the plurality of light emitting diodes 130. The second planarization layer 116b may be formed using a halftone mask. Therefore, the second planarization layer 116b may be formed to have a step.

Specifically, a part of the second planarization layer 116b which is relatively adjacent to the light emitting diode 130 may be formed to have a smaller thickness and a part which is farther from the light emitting diode 130 may be formed to have a larger thickness. A part of the second planarization layer 116b which is adjacent to the light emitting diode 130 is disposed to enclose the light emitting diode 130 and also may be in contact with a side surface of the light emitting diode 130. Therefore, a torn part of the encapsulation film 136 which protects a side surface of the first semiconductor layer 131 of the light emitting diode 130 during the process of separating the light emitting diode 130 from the wafer to be transferred onto the display panel PN may be covered by the second planarization layer 116b. By doing this, thereafter, contacts and short defects of the connection electrodes CE1 and CE2 and the first semiconductor layer 131 may be suppressed.

The third planarization layer 116c is formed to cover upper portions of the second planarization layer 116b and the light emitting diode 130 and a contact hole which exposes the first electrode 134 and the second electrode 135 of the light emitting diode 130 may be formed. The first electrode 134 and the second electrode 135 of the light emitting diode 130 are exposed from the third planarization layer 116c and the third planarization layer 116c is partially disposed in an area between the first electrode 134 and the second electrode 135 to reduce a short defect. The second planarization layer 116b and the third planarization layer 116c may be configured by a single layer or a double layer, and for example, may be formed of photoresist or an acrylic organic material, but are not limited thereto.

In the meantime, the third planarization layer 116c may cover only the light emitting diode 130 and an area adjacent to the light emitting diode 130. The third planarization layer 116c is disposed in an area of the sub pixel SP enclosed by the bank BB and may be disposed in an island shape. Therefore, the bank BB may be disposed in a part of the top surface of the second planarization layer 116b and the third planarization layer 116c may be disposed in the other part of the top surface of the second planarization layer 116b.

The first connection electrode CE1 and the second connection electrode CE2 are disposed on the third planarization layer 116c. The first connection electrode CE1 is an electrode which electrically connects the second electrode 135 of the light emitting diode 130 and the high potential power line VL1. The first connection electrode CE1 may be electrically connected to the second electrode 135 of the light emitting diode 130 through a contact hole formed in the third planarization layer 116c.

The second connection electrode CE2 is an electrode which electrically connects the first electrode 134 of the light emitting diode 130 and the driving transistor DT. The second connection electrode CE2 may be connected to the 1-1-th reflection plate RF1a, the 1-2-th reflection plate RF1b, the third reflection plate RF3, and the fourth reflection plate RF4 of each of the plurality of sub pixels SP through contact holes formed in the third planarization layer 116c, the second planarization layer 116b, the adhesive layer AD, and the second passivation layer 115b. At this time, the 1-1-th reflection plate RF1a, the 1-2-th reflection plate RF1b, the third reflection plate RF3, and the fourth reflection plate RF4 are also connected to the source electrode SE of the driving transistor DT so that the source electrode SE of the driving transistor DT and the first electrode 134 of the light emitting diode 130 may be electrically connected to each other.

In the meantime, in the drawing, it is illustrated that the first electrode 134, the second connection electrode CE2, and the reflection plate RF are electrically connected to the source electrode SE of the driving transistor DT. However, the first electrode 134, the second connection electrode CE2, and the reflection plate RF may be connected to the drain electrode DE of the driving transistor DT, but they are not limited thereto.

A bank BB is disposed on the second planarization layer 116b exposed from the first connection electrode CE1 and the second connection electrode CE2, and the third planarization layer 116c. The bank BB may be disposed to be spaced apart from the light emitting diode 130 with a predetermined interval and may overlap at least partially the reflection plate RF. For example, the bank BB may cover a part of the second connection electrode CE2 formed in the contact holes of the third planarization layer 116c and the second planarization layer 116b. Further, the bank BB may be disposed on the second planarization layer 116b with a predetermined interval from the light emitting diode 130. In this case, the bank BB and the third planarization layer 116c may be spaced apart from each other on a part of the second planarization layer 116b having a smaller thickness. That is, an end of the bank BB and an end of the third planarization layer 116c may be disposed on a part of the second planarization layer 116b having a smaller thickness formed by a halftone mask process to be spaced apart from each other. The bank BB may be formed of an opaque material to reduce color mixture between the plurality of sub pixels SP and for example, may be formed of black resin, but is not limited thereto.

In the meantime, a thickness of a part of the bank BB which is formed in the contact holes of the third planarization layer 116c and the second planarization layer 116b to cover a part of the second connection electrode CE2 and a thickness of a part disposed on the second planarization layer 116b may be different from each other. Specifically, when the part of the bank BB covers a part of the second connection electrode CE2 formed in the contact holes of the third planarization layer 116c and the second planarization layer 116b, since the contact hole is formed from the second passivation layer 115b to the third planarization layer 116c, the bank BB may be disposed below the light emitting diode 130, that is, disposed to be lower than the light emitting diode 130. Therefore, the thickness of the part of the bank BB which covers a part of the second connection electrode CE2 formed in the contact holes of the third planarization layer 116c and the second planarization layer 116b may be larger than the thickness of a part of the bank BB disposed on the second planarization layer 116b.

A first protection layer 117 is disposed on the first connection electrode CE1, the second connection electrode CE2, and the bank BB. The first protection layer 117 is a layer which protects components below the first protection layer 117. The first protection layer 117 may be configured by a single layer or a double layer, and for example, configured by benzocyclobutene, a light-transmitting epoxy, a photoresist, or an acrylic organic material, but is not limited thereto.

A plurality of first pad electrodes PAD1 is disposed in a first pad area PA1 and a second pad area PA2 of the first substrate 110. Each of the plurality of first pad electrodes PAD1 may be configured by a plurality of conductive layers. For example, each of the plurality of first pad electrodes PAD1 includes a first conductive layer PE1a, a second conductive layer PE1b, and a third conductive layer PE1c.

First, the first conductive layer PE1a is disposed on the second interlayer insulating layer 114. The first conductive layer PE1a may be formed of the same conductive material as the source electrode SE and the drain electrode DE and for example, may be configured by copper (Cu), aluminum (Al), molybdenum (Mo), nickel (Ni), titanium (Ti), chrome (Cr), or an alloy thereof, but is not limited thereto.

The first passivation layer 115a is disposed on the first conductive layer PE1a and the second conductive layer PE1b is disposed on the first passivation layer 115a. The second conductive layer PE1b may be formed of the same conductive material as the reflection plate RF and for example, may be configured by silver (Ag), aluminum (Al), molybdenum (Mo), or an alloy thereof, but is not limited thereto.

The third conductive layer PE1c is disposed on the second conductive layer PE1b. The third conductive layer PE1c may be formed of the same conductive material as the first connection electrode CE1 and the second connection electrode CE2, and for example, a transparent conductive material, such as indium tin oxide ITO or indium zinc oxide IZO, but is not limited thereto.

At this time, even though it is not illustrated in the drawings, some of the plurality of conductive layers of the first pad electrode PAD1 are electrically connected to a plurality of wiring lines on the first substrate 110 to supply various signals to a plurality of wiring lines and a plurality of sub pixels SP. For example, the first conductive layer PE1a and/or the second conductive layer PE1b of the first pad electrode PAD1 is connected to the data line DL, the high potential power line VL1, the low potential power line VL2, and the like disposed in the active area AA to transmit signals thereto, respectively.

A first metal layer ML1, a second metal layer ML2, and a plurality of insulating layers may be disposed together below the first pad electrode PAD1. The first metal layer ML1, the second metal layer ML2, and the plurality of insulating layers are disposed below the first pad electrode PAD1 to adjust a step of the first pad electrode PAD1. For example, the buffer layer 111, the gate insulating layer 112, the first metal layer ML1, the first interlayer insulating layer 113, and the second metal layer ML2 may be sequentially disposed between the first pad electrode PAD1 and the first substrate 110. The first metal layer ML1 may be formed of the same conductive material as the gate electrode GE and the second metal layer ML2 may be formed of the same conductive material as the 1-2-th capacitor electrode C1b. However, the plurality of insulating layers, the first metal layer ML1, and the second metal layer ML2 below the first pad electrode PAD1 may be omitted depending on a design and are not limited thereto.

A second substrate 120 is disposed below the first substrate 110. The second substrate 120 is a substrate which supports components disposed below the display device 100 and may be an insulating substrate. For example, the second substrate 120 may be formed of glass or resin. Further, the second substrate 120 may include polymer or plastic. The second substrate 120 may be formed of the same material as the first substrate 110. In some exemplary embodiments, the second substrate 120 may be formed of a plastic material having flexibility.

A bonding layer BDL is disposed between the first substrate 110 and the second substrate 120. The bonding layer BDL may be formed of a material which is cured by various curing methods to bond the first substrate 110 and the second substrate 120. The bonding layer BDL may be disposed only in a partial area between the first substrate 110 and the second substrate 120 or may be disposed in the entire area therebetween.

A plurality of second pad electrodes PAD2 is disposed on a rear surface of the second substrate 120. The plurality of second pad electrodes PAD2 is electrodes which transmit a signal from a driving component disposed on the rear surface of the second substrate 120 to a plurality of side lines SRL and a plurality of first pad electrodes PAD1 and a plurality of wiring lines on the first substrate 110. The plurality of second pad electrodes PAD2 is disposed in an end portion of the second substrate 120 in the non-active area NA to be electrically connected to the side line SRL which covers the end portion of the second substrate 120.

At this time, the plurality of second pad electrodes PAD2 may be also disposed so as to correspond to the plurality of pad areas. The plurality of first pad electrodes PAD1 may be disposed to correspond to the plurality of second pad electrodes PAD2, respectively, and then the first pad electrode PAD1 and the second pad electrode PAD2 which overlap each other may be electrically connected through the side line SRL.

Each of the plurality of second pad electrodes PAD2 includes a plurality of conductive layers. For example, each of the plurality of second pad electrodes PAD2 includes a fourth conductive layer PE2a, a fifth conductive layer PE2b, and a sixth conductive layer PE2c.

First, the fourth conductive layer PE2a is disposed below the second substrate 120. The fourth conductive layer PE2a may be configured by a conductive material such as copper (Cu), aluminum (Al), molybdenum (Mo), nickel (Ni), titanium (Ti), chrome (Cr), or an alloy thereof, but is not limited thereto.

The fifth conductive layer PE2b is disposed below the fourth conductive layer PE2a. The fifth conductive layer PE2b may be configured by a conductive material, such as copper (Cu), aluminum (Al), molybdenum (Mo), nickel (Ni), titanium (Ti), chrome (Cr), or an alloy thereof, but is not limited thereto.

The sixth conductive layer PE2c is disposed below the fifth conductive layer PE2b. The sixth conductive layer PE2c is formed of a conductive material, for example, a transparent conductive material, such as indium tin oxide ITO or indium zinc oxide IZO, but is not limited thereto.

The second protection layer 121 is disposed in the remaining area of the second substrate 120. The second protection layer 121 may protect various wiring lines and driving components formed on the second substrate 120. The second protection layer 121 may be configured by a single layer or a double layer, and for example, configured by benzocyclobutene, a light-transmitting epoxy, a photoresist, or an acrylic organic insulating material, but is not limited thereto.

Even though it is not illustrated in the drawing, a driving component including a plurality of flexible films and a printed circuit board may be disposed on a rear surface of the second substrate 120. The plurality of flexible films is components in which various components such as a data driver IC are disposed on a base film having a ductility to supply signals to the plurality of sub pixels SP. The printed circuit board is a component which is electrically connected to the plurality of flexible films to supply signals to the driving IC. On the printed circuit board, various components for supplying various signals to the driving IC may be disposed.

For example, the fourth conductive layer PE2a and/or the fifth conductive layer PE2b of the second pad electrode PAD2 extends to the plurality of flexible films disposed on the rear surface of the second substrate 120 to be electrically connected to the plurality of flexible films. The plurality of flexible films may supply various signals to the plurality of side lines SRL, the plurality of first pad electrodes PAD1, the plurality of wiring lines, and the plurality of sub pixels SP through the second pad electrode PAD2. Therefore, the signal from the driving component may be transmitted to the signal line and the plurality of sub pixels SP on the front surface of the first substrate 110 through the plurality of second pad electrodes PAD2 of the second substrate 120, the side line SRL, and the plurality of first pad electrodes PAD1 of the first substrate 110.

Next, the plurality of side lines SRL is disposed on the side surfaces of the first substrate 110 and the second substrate 120. The plurality of side lines SRL may electrically connect the plurality of first pad electrodes PAD1 formed on the top surface of the first substrate 110 and the plurality of second pad electrodes PAD2 formed on the rear surface of the second substrate 120. The plurality of side lines SRL may be disposed so as to enclose the side surface of the display device 100. Each of the plurality of side lines SRL may cover the first pad electrode PAD1 at an end portion of the first substrate 110, a side surface of the first substrate 110, a side surface of the second substrate 120, and the second pad electrode PAD2 at an end portion of the second substrate 120. For example, the plurality of side lines SRL may be formed by a pad printing method using a conductive ink including, for example, silver (Ag), copper (Cu), molybdenum (Mo), chrome (Cr), and the like.

A side insulating layer 140 which covers the plurality of side lines SRL is disposed. The side insulating layer 140 may be formed on the top surface of the first substrate 110, the side surface of the first substrate 110, the side surface of the second substrate 120, and the rear surface of the second substrate 120 to cover the side line SRL. The side insulating layer 140 may protect the plurality of side lines SRL.

In the meantime, when the plurality of side lines SRL is formed of a metal material, there may be a problem in that external light is reflected from the plurality of side lines SRL or light emitted from the light emitting diode 130 is reflected from the plurality of side lines SRL to be visibly recognized by the user. Therefore, the side insulating layer 140 is configured to include a black material to suppress reflection of the external light. For example, the side insulating layer 140 is formed by a pad printing method using an insulating material including a black material, for example, a black ink.

A seal member 150 which covers the side insulating layer 140 is disposed. The seal member 150 is disposed so as to enclose the side surface of the display device 100 to protect the display device 100 from external impacts, moisture, and oxygen. For example, the seal member 150 may be formed of polyimide (PI), poly urethane, epoxy, or acryl-based insulating material, but is not limited thereto.

An optical film MF is disposed on the seal member 150, the side insulating layer 140, and the first protection layer 117. The optical film MF may be a functional film which implements a higher quality of images while protecting the display device 100. For example, the optical film MF may include an anti-scattering film, an anti-glare film, an anti-reflecting film, a low-reflecting film, an Oled transmittance controllable film, a polarizer, or the like, but is not limited thereto.

In the meantime, an edge of the seal member 150 and an edge of the optical film MF may be disposed on the same line. The optical film MF having a larger size is attached above the first substrate 110 during the manufacturing process of the display device 100 and the seal member 150 which covers the side insulating layer 140 may be formed. Thereafter, the laser is irradiated on the seal member 150 and the optical film MF so as to correspond to an edge of the display device 100 to cut parts of the seal member 150 and the optical film MF. Accordingly, the size of the display device 100 is adjusted by an outer periphery cutting process of the seal member 150 and the optical film MF and the edge of the display device 100 may be formed to be flat.

In the meantime, the display device 100 according to the exemplary embodiment of the present disclosure may be formed with a zero bezel structure with substantially no bezel using the side line SRL. At this time, in the zero bezel structure, a separate mechanical tool which encloses the display panel PN and serves as a ground may not be formed. Therefore, as compared with a general display device 100 with a mechanical tool, in the display device 100 with a zero bezel structure, the static electricity may more easily enter into the display panel PN through the side line SRL on the side surface of the display panel PN and the first pad electrode PAD1 connected to the side line SRL. Therefore, in the display device 100 according to the exemplary embodiment of the present disclosure, an electrostatic discharge circuit (ESD) is formed in the display panel PN to protect the display panel PN from the static electricity entering the display panel PN.

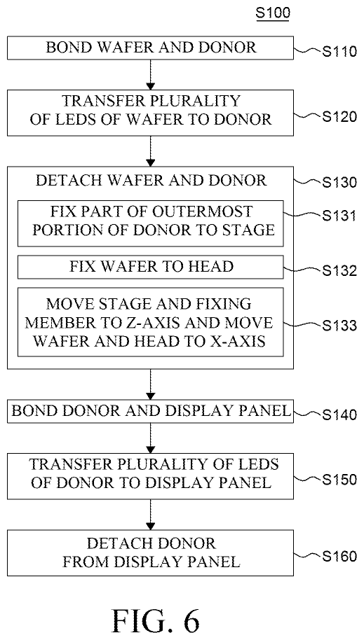

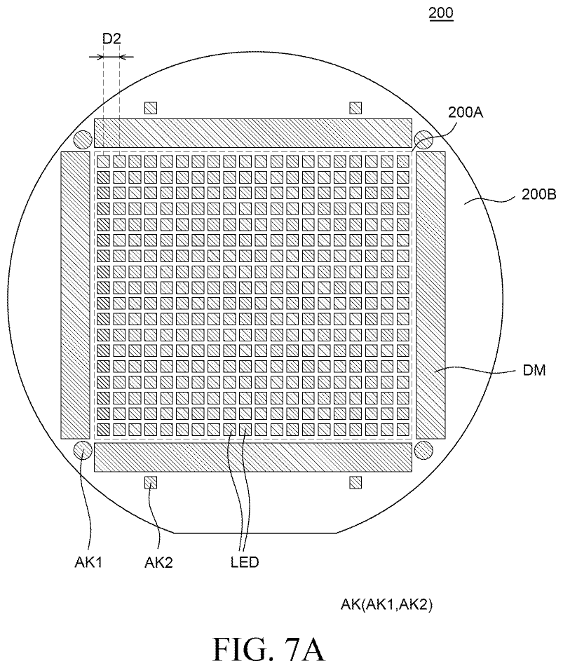

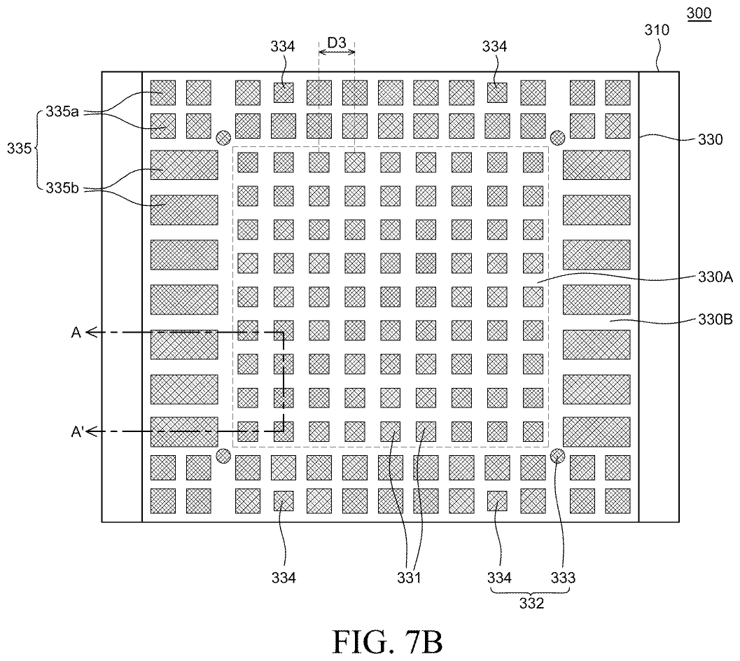

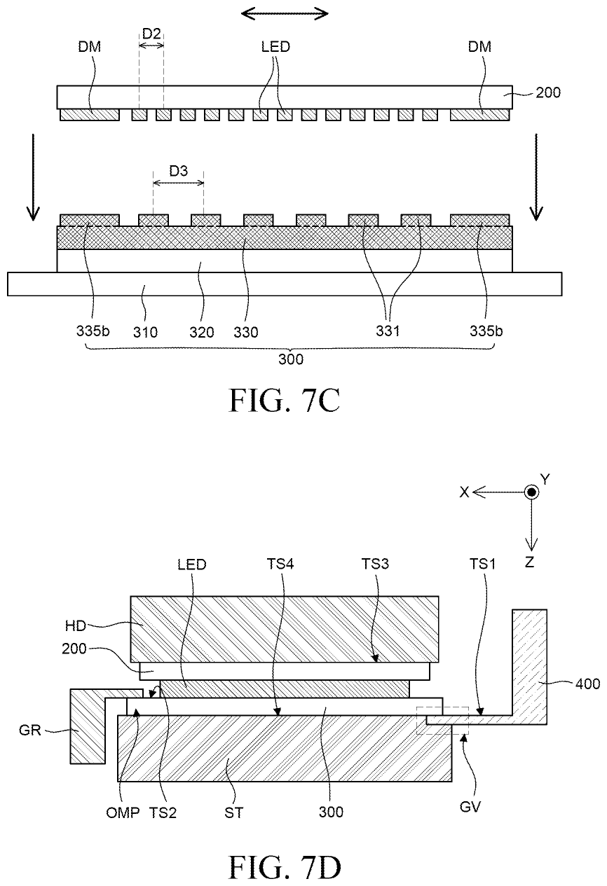

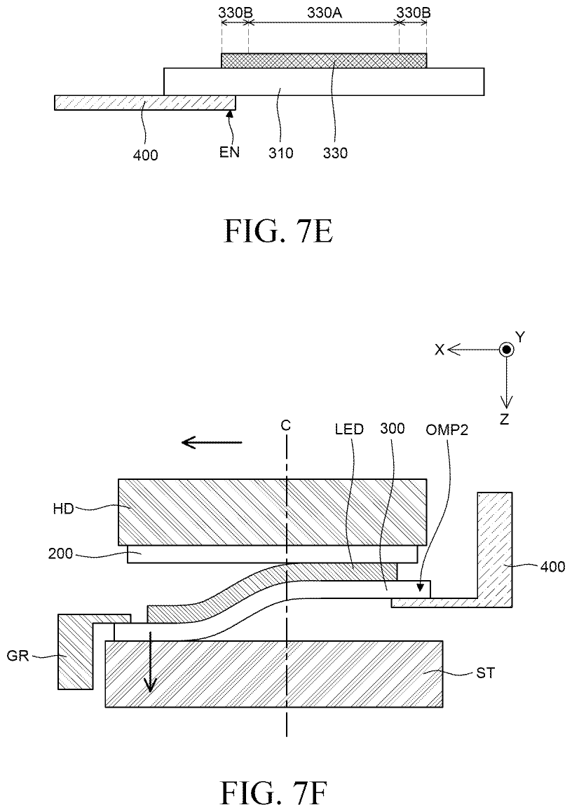

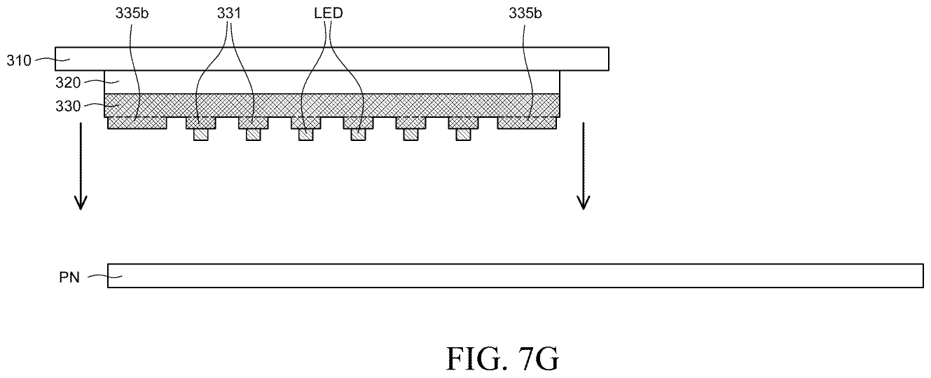

Hereinafter, a transfer device and a transfer method of a light emitting diode and a method for manufacturing a display device using the same, according to an exemplary embodiment of the present disclosure will be described with reference to FIGS. 6 to 7G.

FIG. 6 is a process flowchart for explaining a manufacturing method of a display device according to an exemplary embodiment of the present disclosure. FIGS. 7A to 7G are schematic process diagrams for explaining a transfer device and a transfer method of a light emitting diode and a method for manufacturing a display device using the same, according to an exemplary embodiment of the present disclosure. Specifically, FIGS. 7A to 7F are schematic process diagrams for explaining a primary transfer process and FIG. 7G is a schematic process diagram for explaining a secondary transfer process. FIG. 7A is a plan view of a wafer 200 and FIG. 7B is a plan view of a donor 300. FIG. 7C is a cross-sectional view taken along the line A-A′ of FIG. 7B. FIG. 7D is a schematic cross-sectional view for explaining a placement position of a support member 400 and for the convenience of description, only a base layer 310 and a resin layer 330 of the donor 300 are illustrated. FIGS. 7E and 7F are schematic cross-sectional views for explaining a detaching process of a wafer 200 and a donor 300 and for the convenience of description, schematically illustrate the donor 300, the wafer 200, and a plurality of light emitting diodes LED. FIG. 7G is a cross-sectional view of a donor 300 and a display panel PN for explaining a secondary transfer process.

First, referring to FIG. 6, a primary transfer process is performed to transfer a plurality of light emitting diodes LED on the wafer 200 to the donor 300 and a secondary transfer process is performed to transfer a plurality of light emitting devices LED on the donor 300 to the display panel PN. Therefore, the plurality of light emitting diodes LED is transferred from the wafer 200 to the donor 300 and from donor 300 to the display panel PN to complete a manufacturing process of the display device 100.

Hereinafter, the first transfer process will be described with reference to FIGS. 6, 7A to 7F first.

Referring to FIGS. 6 and 7A together, the wafer 200 is a substrate on which the plurality of light emitting diodes LED is formed. A crystal layer is grown by forming a material, such as gallium nitride GaN or indium gallium nitride InGaN, which configures the plurality of light emitting diodes LED on the wafer 200, the crystal layer is cut into individual chips and an electrode is formed to form the plurality of light emitting diodes LED. The wafer 200 may be formed of sapphire, silicon carbide SiC, gallium nitride GaN, zinc oxide ZnO, or the like, but is not limited thereto.

At this time, a plurality of light emitting diodes LED which emits light with the same color may be formed or a plurality of light emitting diodes LED which emits light with different colors may be formed, on one wafer 200. Hereinafter, the description will be made by assuming that the plurality of light emitting diodes LED which emits light with the same color is formed on one wafer 200.

The wafer 200 includes an active area 200A and an outer peripheral area 200B. In the active area 200A, the plurality of light emitting diodes LED is formed and in the outer peripheral area 200B which is disposed at the outside of the active area 200A, at least one or more dams DM and a plurality of alignment keys AK are disposed.

The plurality of light emitting diodes LED is disposed in the active area 200A. The plurality of light emitting diodes LED may be formed by forming an epitaxial layer on the wafer 200, and then patterning the epitaxial layer. Specifically, after growing materials for forming an n-type semiconductor layer NL, an emission layer EL, a p-type semiconductor layer PL which configure the plurality of light emitting diodes LED on the wafer 200, an isolation process for patterning the material into a plurality of pieces is performed to form a plurality of light emitting diodes LED.

The plurality of light emitting diodes LED may be disposed with a second interval D2. The second interval D2 may be an interval from a center of one light emitting diode LED, among a plurality of light emitting diodes LED to a center of an adjacent light emitting diode LED. The second interval D2 may be an interval smaller than a first interval D1 which is an interval between the plurality of pixels PX of the display panel PN.

The plurality of alignment keys AK disposed in an outer peripheral area 200B includes a first alignment key AK1 and a second alignment key AK2. The first alignment key AK1 and the second alignment key AK2 may be disposed in the outer peripheral area 200B. However, the first alignment key AK1 and the second alignment key AK2 are not limited to those illustrated in the drawing and the number and the position may be designed in various ways.

The first alignment key AK1 is a component used to align the wafer 200 and the donor 300. The first alignment key AK1 is a mark for adjusting an alignment and parallelism with the donor 300 when the plurality of light emitting diodes LED of the wafer 200 is transferred onto the donor 300. The first alignment key AK1 of the wafer 200 and an alignment bump 332 of the donor 300 are aligned to adjust the alignment and the parallelism of the wafer 200 and the donor 300.

For example, the first alignment key AK1 may be a metal pattern which is disposed between a plurality of dams DM in the outer peripheral area 200B or above or below the plurality of dams DM. Therefore, the first alignment key AK1 is detected using a vision method to align the wafer 200 and the donor 300. In this case, even though the first alignment key AK1 is formed on the dam DM to be described below, the first alignment key AK1 is a sort of metal pattern so that a step caused in the wafer 200 and the donor 300 by the first alignment key AK1 may be insignificant. Accordingly, the first alignment key AK1 may be formed in the outer peripheral area 200B without being limited by the position of the dam DM.

The second alignment key AK2 is a component used to align the donor 300 and the display panel PN. When the plurality of light emitting diodes LED of the wafer 200 is transferred onto the donor 300, the second alignment key AK2 may be transferred to the donor 300 together with the plurality of light emitting diodes LED. Thereafter, the alignment and the parallelism of the donor 300 and the display panel PN may be adjusted using the second alignment key AK2 on the donor 300.

The first alignment key AK1 and the second alignment key AK2 may be formed together when the plurality of light emitting didoes LED is formed or formed by a separate process from the plurality of light emitting diodes LED. If the first alignment key AK1 and the second alignment key AK2 are formed together with the plurality of light emitting didoes LED, the first alignment key AK1 and the second alignment key AK2 may be formed with the same material as at least a part of a material of the plurality of light emitting didoes LED. However, the material and the forming process of the first alignment key AK1 and the second alignment key AK2 may be configured in various forms depending on the design, but are not limited thereto.

Shapes and sizes of the first alignment key AK1 and the second alignment key AK2 may be configured in various forms. In order to identify the first alignment key AK1 and the second alignment key AK2 disposed in the outer peripheral area 200B, the first alignment key AK1 and the second alignment key AK2 may have different shapes or sizes. For example, the first alignment key AK1 may be larger than the second alignment key AK2, but is not limited thereto.

One or more dams DM is disposed in the outer peripheral area 200B. The dam DM is a configuration which improves a contact area with the donor 300 to be described below to improve a bonding strength with the donor 300. One or more dams DM may be formed together with the plurality of light emitting diodes LED. Specifically, during the process of patterning the epitaxial layer into a plurality of pieces, a part of the epitaxial layer which overlaps the outer peripheral area 200B remains without being patterned to form one or more dams DM. Therefore, the height of the dam DM may be formed to be substantially the same as a height of the plurality of light emitting didocs LED.

In the meantime, a minimum width of the dam DM may be designed in consideration of a width of an interval at which the wafer 200 and the donor 300 are most shifted and a width of an area in which the plurality of dam bumps 335 of the donor 300 is disposed. According to a selective transfer method of transferring only some of the plurality of light emitting diodes LED on the wafer 200 to the donor 300, a bonding position of the donor 300 and the wafer 200 may slightly vary. For example, the bonding position of the donor 300 and the wafer 200 may vary within a third interval D3 which is an interval of the plurality of chip bumps 331 of the donor 300 to be described below. At this time, in order to improve a bonding strength of the donor 300 and the wafer 200, at least a part of the dam DM may be in contact with the plurality of dam bumps 335 of a non-transferring area 330B of the donor 300 to be described below. In this case, in order to allow at least a part of the dam DM and a plurality of dam bumps 335 to be in contact with each other, it needs to be configured in an interval at which the donor 300 and the wafer 200 are the most shifted, for example, a third interval D3 or larger. If a minimum width of the dam DM is equal to or smaller than the third interval D3, it may be difficult to bond at least a part of the dam DM with the non-transferring area 330B of the donor 300 and the bonding strength of the donor 300 and the wafer 200 may be lowered. Therefore, a minimum width of the dam DM is configured to be equal to or larger than an interval at which the wafer 200 and the donor 300 are the most shifted to ensure a predetermined level or higher of a bonding strength of the wafer 200 and the donor 300 during the transfer process.

An interval between the dam DM of the outer peripheral area 200B and a light emitting diode LED disposed in an outermost side of the active area 200A may be equal to or larger than an interval from an outer periphery of one light emitting diode LED to an outer periphery of a light emitting diode LED adjacent to one light emitting diode LED. At this time, the interval from an outer periphery of one light emitting diode LED to an outer periphery of the adjacent light emitting diode LED is smaller than the second interval D2. The interval between the dam DM in the outer peripheral area 200B and the light emitting diode LED disposed in the outermost side of the active area 200A is formed to be equal to or larger than an interval from the outer periphery to the outer periphery of the light emitting diode LED. By doing this, the interference of the light emitting didoes LED during the transfer process may be reduced or minimized, which will be described below with reference to FIG. 7F.

In the meantime, in FIG. 7A, it is illustrated that a dam DM is disposed to adjacent to each of four sides of the active area 200A. However, the dam DM may be formed to extend to an edge of the wafer 200 or formed in the entire outer peripheral area 200B excluding a part in which a structure such as a plurality of alignment keys AK is formed to be integrally formed, but is not limited thereto.

In the meantime, the second alignment key AK2 and the active area 200A may be disposed with the dam DM therebetween. The second alignment key AK2 may be disposed at the outside of the dam DM in the outer peripheral area 200B. When the second alignment key AK2 is formed by the same process as the plurality of light emitting diodes LED, at the time of patterning the epitaxial layer for forming the plurality of light emitting diodes LED, the second alignment key AK2 is also patterned to be formed. That is, the epitaxial layer formed in the outer peripheral area 200B is patterned to form the second alignment key AK2. At this time, after sufficiently ensuring an area to form the dam DM, the second alignment key AK2 may be formed at the outside of the dam DM. Therefore, the second alignment key AK2 may be spaced apart from the active area 200A with a minimum width of the dam DM, for example, an interval which is equal to or larger than the third interval D3.

Referring to FIG. 7B, the donor 300 includes a base layer 310, an adhesive layer 320, a resin layer 330, a plurality of chip bumps 331, a plurality of alignment bumps 332, and a plurality of dam bumps 335.

The base layer 310 is a configuration for supporting various compositions included in the donor 300 and may be formed of a material more rigid than at least the resin layer 330 to reduce or minimize the bending of the resin layer 330. The base layer 310 is disposed below the resin layer 330 to support the resin layer 330, the plurality of chip bumps 331 and the plurality of alignment bumps 332. For example, the base layer 310 may include polymer, plastic, or the like or may be also formed of poly carbonate (PC) or polyethylene terephthalate (PET), but is not limited thereto.

The resin layer 330 is disposed on the base layer 310. The resin layer 330 may support the plurality of chip bumps 331 to which the plurality of light emitting diodes LED is attached, during the transfer process. The resin layer 330 may be formed by a polymer material having viscoelasticity, for example, the resin layer 330 may be configured by poly dimethyl siloxane (PDMS), poly urethane acrylate (PUA), polyethylene glycol (PEG), polymethylmethacrylate (PMMA), polystyrene (PS), epoxy resin, urethane resin, acrylic resin, or the like. However, it is not limited thereto.

The resin layer 330 includes a transferring area 330A and a non-transferring area 330B. The transferring area 330A is an area in which the plurality of chip bumps 331 is disposed. The transferring area 330A is an area in which the plurality of chip bumps 331 to be attached with the plurality of light emitting diodes LED is disposed and may be disposed so as to overlap at least a part of the wafer 200 or the display panel PN during the transfer process.

The non-transferring area 330B is an area in which the plurality of alignment bumps 332 and the plurality of dam bumps 335 are disposed. In the non-transferring area 330B, a second alignment key AK2 of the wafer 200 may be transferred.

The plurality of chip bumps 331 is bumps to which the plurality of light emitting diodes LED is disposed and extends from one surface of the resin layer 330. The plurality of chip bumps 331 may be integrally formed with the resin layer 330 and may be formed of a polymer material having viscoelasticity, which is the same as the resin layer 330. For example, the plurality of chip bumps 331 may be formed of poly dimethyl siloxane (PDMS), poly urethane acrylate (PUA), polyethylene glycol (PEG), polymethylmethacrylate (PMMS), polystyrene (PS), epoxy resin, urethane resin, acrylic resin, or the like, but is not limited thereto.

The plurality of light emitting diodes LED may be temporarily attached onto top surfaces of the plurality of chip bumps 331. The plurality of light emitting diodes LED which is formed on the wafer 200 may be transferred onto the top surfaces of the plurality of chip bumps 331. The plurality of light emitting diodes LED may temporarily maintain a state being attached onto the top surfaces of the plurality of chip bumps 331 before being transferred onto the display panel PN. Further, the donor 300 which includes a resin layer 330 formed of a flexible material and a plurality of chip bumps 331 which is integrally formed with the resin layer 330 and is temporarily attached with the plurality of light emitting diodes LED thereabove may be defined as a flexible substrate.

At this time, the plurality of chip bumps 331 may be disposed with a third interval D3. The third interval D3 may be larger than the second interval D2 which is an interval of the plurality of light emitting diodes LED of the wafer 200. The third interval D3 of the plurality of chip bumps 331 may be N times the second interval D2 of the plurality of light emitting diodes LED of the wafer 200. In this case, only some of the plurality of light emitting diodes LED disposed on the wafer 200 with the second interval D2 may be transferred onto the plurality of chip bumps 331 of the donor 300. For example, when the third interval D3 is twice the second interval D2, an odd-numbered light emitting diode LED or an even-numbered light emitting diode LED in one line may be selectively transferred onto the plurality of chip bumps 331.

The third interval D3 may be N times or 1/N times a first interval D1 which is an interval of the plurality of pixels PX of the display panel PN, that is, a pixel pitch. Specifically, the third interval D3 from a center of one chip bump 331 to a center of an adjacent chip bump 331 may be N times or 1/N times the pixel pitch. The interval of the plurality of chip bumps 331 is formed to be N times or 1/N times the pixel pitch so that the pixel pitch of the display panel PN is changed by one donor 300 to transfer the plurality of light emitting diodes LED. The plurality of light emitting diodes LED disposed on the plurality of chip bumps 331 is selectively transferred in consideration of the third interval D3 which is an interval of the plurality of chip bumps 331 and the first interval D1 which is a pixel pitch to change the pixel pitch. For example, when the pixel pitch is formed to be the same as the second interval D2 which is an interval of the plurality of chip bumps 331, the plurality of light emitting diodes LED on the plurality of chip bumps 331 may be transferred to the display panel PN at one time. For example, when the pixel pitch is formed to be twice the third interval D3 of the plurality of chip bumps 331, only the plurality of light emitting diodes LED on the odd-numbered chip bump 331 or the even-numbered chip bump 331, among the plurality of chip bumps 331 disposed on the same row is transferred. By doing this, the pixel pitch may be adjusted. However, the placement and the interval of the plurality of chip bumps 331 may vary depending on a design, and are not limited thereto.

Sizes of the plurality of chip bumps 331 may be larger than the sizes of the plurality of light emitting diodes LED. Sizes of the top surfaces of the plurality of chip bumps 331 are formed to be larger than the plurality of light emitting diodes LED so that even though an alignment error of the donor 300 and the wafer 200 is generated, the plurality of light emitting diodes LED may be seated on the plurality of chip bumps 331. Accordingly, the sizes of the top surfaces of the plurality of chip bumps 331 may be formed to be larger than the plurality of light emitting diodes LED in consideration of the alignment error of the wafer 200 and the donor 300.

In the non-transferring area 330B, the plurality of alignment bumps 332 and the plurality of dam bumps 335 are disposed.

The plurality of alignment bumps 332 includes a plurality of first alignment bumps 333 and a plurality of second alignment bumps 334.

The plurality of first alignment bumps 333 is components used to align the wafer 200 and the donor 300. The plurality of first alignment bumps 333 may be disposed so as to correspond to the first alignment key AK1 of the wafer 200. For example, the first alignment key AK1 of the wafer 200 and the first alignment bump 333 of the donor 300 are aligned to adjust the alignment and the parallelism of the wafer 200 and the donor 300. At this time, the first alignment bumps 333 and the first alignment key AK1 may have different shapes or sizes to be easily identified. For example, any one of the first alignment bump 333 and the first alignment key AK1 has a donut shape with a hole in the center and the other one may be formed to have a circular shape overlapping the hole. Even though in FIGS. 4A and 4B, it is illustrated that the first alignment key AK1 of the wafer 200 and the first alignment bump 333 of the donor 300 have a circular shape, but the shapes of the first alignment key AK1 of the wafer 200 and the first alignment bump 333 are not limited thereto.

The second alignment bump 334 may be disposed so as to correspond to the second alignment key AK2 of the wafer 200. For example, two second alignment bumps 334 may be disposed in a non-transferring area 330B disposed above the transferring area 330A and two second alignment bumps 334 may be disposed in a non-transferring area 330B disposed below the transferring area 330A. The wafer 200 and the donor 300 are aligned by aligning the first alignment key AK1 of the wafer 200 and the first alignment bump 333 of the donor 300. Thereafter, the plurality of light emitting diodes LED of the wafer 200 may be transferred to the plurality of chip bumps 331 of the donor 300 and the second alignment key AK2 of the wafer 200 may be transferred to the second alignment bump 334 of the donor 300. At this time, the second alignment key AK2 which is transferred to the donor 300 may be used to align the display panel PN and the donor 300.

The plurality of dam bumps 335 is in contact with the dam DM of the wafer 200 during the transfer process to improve the bonding strength of the wafer 200 and the donor 300 and may reduce or minimize the deformation of the plurality of chip bumps 331 due to the shock which is applied to the donor 300. For example, after bonding the wafer 200 and the donor 300, when the plurality of light emitting diodes LED is transferred onto the donor 300, the plurality of light emitting diodes LED moves onto the donor 300 to apply the shock to the donor 300. When the shock is applied to the donor 300, the positions or the shapes of the resin layer 330 and the plurality of chip bumps 331 of the transferring area 330A may be modified. At this time, the deformation of the resin layer 330 and the plurality of chip bumps 331 of the transferring area 330A may be reduced or minimized while maintaining a bonded state of the plurality of dam bumps 335 of the non-transferring area 330B which is disposed to enclose the transferring area 330A and the wafer 200. Further, the plurality of dam bumps 335 is in contact with one or more dams DM of the wafer 200 to allow the wafer 200 and the donor 300 to maintain the bonded state.

At least one or more dam bumps 335 may be disposed to be adjacent to the plurality of alignment bumps 332. At least one or more dam bumps 335 may be disposed between the plurality of alignment bumps 332 and the transferring area 330A or between the plurality of alignment bumps 332 and the edge of the resin layer 330. During the transfer process, in order to reduce or minimize the separation of the donor 300 and the wafer 200 in the area in which the plurality of alignment bumps 332 is disposed, due to the weakened bonding strength of the donor 300 and the wafer 200, at least one or more dam bumps 335 may be disposed to be adjacent to the plurality of alignment bumps 332.

The plurality of dam bumps 335 may be equal to or larger than the plurality of chip bumps 331 and may have the same height as the plurality of chip bumps 331. When the plurality of dam bumps 335 is equal to or larger than the plurality of chip bumps 331, the plurality of dam bumps may be formed in various forms. For example, a plurality of first dam bumps 335a disposed in the non-transferring area 330B above and below the transferring area 330A, among the plurality of dam bumps 335, may be formed in a square shape and may be disposed to be spaced apart from each other. For example, a plurality of second dam bumps 335b disposed in the non-transferring area 330B at a left side and a right side of the transferring area 330A, among the plurality of dam bumps 335, may be formed in a rectangular shape. However, shapes of the plurality of dam bumps 335 may be configured in various shapes, but are not limited thereto.

A minimum width of an area in which the plurality of dam bumps 335 is disposed may be equal to a minimum width of the dam DM. For example, a minimum width of the area in which the plurality of dam bumps 335 is disposed may be configured to be equal to or larger than the third interval D3 which is an interval at which the wafer 200 and the donor 300 are the most shifted. At this time, in the drawing, it is illustrated that the plurality of dam bumps 335 is disposed in the entire non-transferring area 330B so that the width of the non-transferring area 330B in which the plurality of dam bumps 335 is disposed corresponds to a minimum width of the dam DM of the wafer 200. However, the plurality of dam bumps 335 is disposed only in a part of the non-transferring area 330B so that the width of the non-transferring area 330B and the size of the area in which the plurality of dam bumps 335 is disposed may be different, but are not limited thereto.

The plurality of dam bumps 335 which is spaced apart from each other is disposed in the non-transferring area 330B of the donor 300 to reduce the trapping of the air between the dam DM and the dam bump 335 when the wafer 200 and the donor 300 are bonded. This will be described below with reference to FIG. 7C.

In the meantime, the plurality of chip bumps 331 is not disposed on the donor 300, but the plurality of light emitting diodes LED may be directly transferred onto the resin layer 330. That is, the donor 300 may not include a separate chip bump 331. A structure of the donor 300 may vary depending on a shape, a placement, and a transferring method of the plurality of light emitting diodes LED, but is not limited thereto. Hereinafter, for the convenience of description, it is assumed that the donor 300 includes a plurality of chip bumps 331 and the plurality of light emitting diodes LED is transferred onto the plurality of chip bumps 331, respectively.

An adhesive layer 320 is disposed between the resin layer 330 and the base layer 310. The adhesive layer 320 bonds the resin layer 330 and the display panel PN. The adhesive layer 320 may be formed of a material having adhesiveness and for example, may be formed of an optically clear adhesive (OCA), a pressure sensitive adhesive (PSA), or the like, but is not limited thereto.

However, the adhesive layer 320 may be omitted depending on the design. For example, the resin layer 330 may be formed by immediately coating a material which forms the resin layer 330 on the base layer 310 and then curing the material. In this case, even though the adhesive layer 320 is not disposed, the resin layer 330 may be attached onto the base layer 310 so that the adhesive layer 320 may be omitted depending on the design, but is not limited thereto.

Next, referring to FIG. 7C together, the wafer 200 on which a plurality of light emitting devices LED is formed and the donor 300 are input into process equipment. The wafer 200 and the donor 300 input into the process equipment are aligned. In a state in which the wafer 200 and the donor 300 are disposed such that the plurality of light emitting diodes LED on the wafer 200 and the plurality of chip bumps 331 of the donor 300 are opposite to each other, the wafer 200 and the donor 300 may be aligned. For example, a center of the first alignment key AK1 of the wafer 200 and a center of the first alignment bump 333 of the donor 300 are aligned to align the wafer 200 and the donor 300.

After completing the alignment of the wafer 200 and the donor 300, the wafer 200 and the donor 300 are bonded (S110). The plurality of light emitting diodes LED of the active area 200A of the wafer 200 corresponds to the plurality of chip bumps 331 of the transferring area 330A of the donor 300. The wafer 200 and the donor 300 are bonded such that the dam DM of the outer peripheral area 200B of the wafer 200 corresponds to the plurality of dam bumps 335 of the non-transferring area 330B of the donor 300.

At this time, the dam DM of the wafer 200 and the plurality of dam bumps 335 of the donor 300 are bonded to increase a contact area of the wafer 200 and the donor 300 and the wafer 200 and the donor 300 may be uniformly bonded. For example, the dam DM which is disposed to enclose the active area 200A of the wafer 200 is bonded to the plurality of dam bumps 335 of the donor 300 so that the entire wafer 200 and the entire donor 300 may be uniformly bonded. If the dam DM is formed in only a part of four sides of the active area 200A in the wafer 200, a difference in a bonding strength is generated between an area in which the dam DM is formed and an area in which the dam DM is not formed so that it may be difficult to uniformly bond the entire surfaces of the wafer 200 and the donor 300. In this case, a bonding defect of the plurality of light emitting diodes LED of the wafer 200 and the plurality of chip bumps 331 of the donor 300 may be caused. Therefore, the plurality of dams DM is formed in the entire outer peripheral area 200B of the wafer 200 so that the bonding strength of the wafer 200 and the donor 300 may be uniformly improved.

In the non-transferring area 330B of the donor 300 corresponding to the outer peripheral area 200B of the wafer 200, a plurality of dam bumps 335 which is spaced apart from each other is disposed to reduce or minimize the trapping of the air. Specifically, in the outer peripheral area 200B of the wafer 200, the dam DM which is larger than the plurality of dam bumps 335 may be disposed. If the dam bump 335 is formed to have a size corresponding to the dam DM, the contact area of the dam DM and the dam bump 335 is increased to increase the bonding strength of the wafer 200 and the donor 300. However, a non-bonding area due to the air which is trapped by the dam DM and the dam bump 335 may be generated. Therefore, the dam bumps 335 corresponding to the dam DM are formed as a plurality of dam bumps 335 which is spaced apart from each other to move the air to the outside of the wafer 200 and the donor 300 through an empty space between the plurality of dam bumps 335. At this time, the dam bump 335 disposed above or below the transferring area 330A may form an air passage extending to the column direction and the dam bump 335 disposed at the left side or the right side of the transferring area 330A may form an air passage extending to the row direction. Therefore, the plurality of dam bumps 335 which is spaced apart from each other is disposed in the non-transferring area 330B of the donor 300 so that a path through which air moves when the wafer 200 and the donor 300 are bonded may be formed. Further, an area in which the wafer 200 and the donor 300 are not bonded due to the trapped air may be reduced.

Next, the plurality of light emitting diodes LED of the wafer 200 is transferred onto the donor 300 (S120). In a state in which the wafer 200 and the donor 300 are disposed to be opposite to each other, laser may be selectively irradiated onto only a light emitting diode LED to be transferred to the donor 300, among the plurality of light emitting diodes LED. The light emitting diode LED irradiated with the laser is detached from the wafer 200 to be adhered onto the plurality of chip bumps 331 of the donor 300.

The plurality of light emitting diodes LED may be transferred to only some of the plurality of chip bumps 331 of the donor 300 or the plurality of light emitting diodes LED may be transferred to all the plurality of chip bumps 331, depending on the design. For example, when a red light emitting diode LED, a green light emitting diode LED, and a blue light emitting diode LED are transferred onto one donor 300 from different wafers 200 to transfer the red light emitting diode LED, the green light emitting diode LED, and the blue light emitting diode LED to the display panel PN at one time, the light emitting diode LED may be transferred to only some chip bumps 331, among the plurality of chip bumps 331, from one wafer 200. For example, when only one type of light emitting diode LED is transferred onto one donor 300 to transfer only one type of light emitting diode LED to the display panel PN, the light emitting diode LED may be transferred to all the plurality of chip bumps 331 from one wafer 200. However, a type of the light emitting diode LED to be transferred and a position and the number of chip bumps 331 to which the light emitting diode LED is transferred may be designed in various forms during the transfer process in consideration of the second interval D2 which is an interval of the plurality of chip bumps 331 and the first interval D1 which is an interval of the plurality of pixels PX of the display panel PN. However, they are not limited thereto.

In the meantime, at least some of the plurality of second alignment keys AK2 of the wafer 200 may be also transferred to the donor 300. In a state in which the wafer 200 and the donor 300 are disposed to be opposite to each other, laser may be selectively irradiated onto only some second alignment key AK2 to be transferred to the donor 300, among the plurality of second alignment keys AK2. The second alignment key AK2 irradiated with laser is detached from the wafer 200 to be adhered to the second alignment bump 334 of the donor 300.

In this case, when the plurality of second alignment keys AK2 is deviated from the correct position on the plurality of second alignment bumps 334, a plurality of light emitting diode LED maintaining a constant distance from the plurality of second alignment keys AK2 may also be deviated from the correct position on the plurality of chip bumps 331. Therefore, the position of the plurality of light emitting diodes LED may be easily identified by means of the second alignment key AK2. However, the second alignment key AK2 may not be transferred together with the plurality of light emitting diodes LED, but is not limited thereto.

Next, referring to FIGS. 7D to 7F, after transferring the plurality of light emitting diodes LED of the wafer 200 to the donor 300, the wafer 200 and the donor 300 are detached (S130).

First, referring to FIGS. 7D and 7F, a transfer device according to the exemplary embodiment of the present disclosure may include a stage ST, a head HD, a fixing member GR, and a support member 400.

The stage ST may support the wafer 200 and the donor 300 during the process. Therefore, in the stage ST, the bonded wafer 200 and donor 300 may be loaded.

The stage ST may be configured to move in a Z-axis direction during the detachment process of the wafer 200 and the donor 300. The stage ST may be configured to move in the Z-axis direction without moving in the X-axis and Y axis directions. For example, the stage ST may be configured to move in a Z-axis direction to be spaced apart from the head HD, during the detachment process of the wafer 200 and the donor 300.

The stage ST may include a groove GV in which the support member 400 is disposed. The groove GV of the stage ST may be disposed so as to correspond to the other end of one end in which the fixing member GR is disposed, but is not limited thereto.

The support member 400 may be configured to support the donor 300. The support member 400 may be disposed in the groove GV of the stage ST. The support member 400 may be disposed in the groove GV of the stage ST so as to correspond to a center of the donor 300.

As illustrated in FIG. 7D, the support member 400 may have a plate shape. That is, the support member 400 has a flat top surface TS1 and the donor 300 may be disposed on the flat top surface TS1 of the support member 400. However, the shape of the support member 400 is not limited thereto.

The support member 400 may be fixed without moving during the detachment process of the wafer 200 and the donor 300. That is, the support member 400 is configured so as not to move in the X-axis, Y-axis, and Z-axis directions during the detachment process of the wafer 200 and the donor 300 and may maintain a distance from the head HD.

As illustrated in FIG. 7D, the fixing member GR may fix one of the outermost portions OMP of the donor 300. The fixing member GR is disposed in an opposite side of the support member 400 to pressurize the top surface TS2 of the donor 300 toward the stage ST. Therefore, the fixing member GR may fix one of outermost portions OMP of the donor 300 together with the stage ST.

The fixing member GR may be configured to move in a Z-axis direction during the detachment process of the wafer 200 and the donor 300. The fixing member GR may be configured to move in the Z-axis direction without moving in the X-axis and Y axis directions. For example, the fixing member GR may be configured to move in a Z-axis direction to be spaced apart from the head HD, during the detachment process of the wafer 200 and the donor 300.

The head HD may fix one surface TS3 of the wafer 200. The head HD is disposed to be opposite to the top surface TS4 of the stage ST to fix one surface TS3 of the wafer 200. In order to fix the wafer 200, the head HD may include a plurality of holes for sucking the wafer 200 with vacuum or a separate fixing member, but is not limited thereto.

The head HD may be configured to move in the X-axis direction during the detachment process of the wafer 200 and the donor 300. The head HD may be configured to move in the X-axis direction without moving in the Z-axis direction. For example, the head HD may be configured to move in the X-axis direction to be spaced apart from the support member 400, during the detachment process of the wafer 200 and the donor 300.

In the meantime, the bonded wafer 200 and donor 300 may be located between the stage ST and the head HD. The wafer 200 may be disposed so as to correspond to the head HD and the donor 300 may be disposed so as to correspond to the stage ST.

However, in the present disclosure, even though it has been described that the wafer 200 and the donor 300 move to the stage ST for the detachment process of the wafer 200 and the donor 300, the bonding and detachment processes of the wafer 200 and the donor 300 may be performed on the same stage, but are not limited thereto.

At this time, referring to FIG. 7E, an end EN of the support member 400 may be disposed in the non-transferring area 330B so as to overlap the base layer 310 and the resin layer 330 of the donor 300. In particular, the end EN of the support member 400 may be disposed so as to overlap the base layer 310 and the resin layer 330 of the donor 300 from a plan view. The support member 400 serves to support the donor 300 so that the support member 400 may be disposed so as to overlap the base layer 310 and the resin layer 330 of the donor 300. However, the support member 400 may be configured by a material having rigidity so that the support member 400 should not overlap the transferring area 330A of the donor 300. That is, as shown in FIG. 7E, the support member 400 (or more specifically, the end EN of the support member 400) does overlap with the non-transferring area 330B but does not overlap with the transferring area 330A from a plan view. When the support member 400 overlaps the transferring area 330A of the donor 300, the transferring area 330A which overlaps the support member 400 is relatively rigid, but the transferring area 330A which does not overlap the support member 400 is less rigid. Therefore, the light emitting diode may not be uniformly transferred for every area.

Next, one of outermost portions OMP1 of the donor 300 is physically fixed to the stage ST (S131). One edge of the plurality of edges of the donor 300 or at least one edge of four edges of the donor 300 may be fixed to the stage ST using the fixing member GR. The remaining part of the donor 300 which is not fixed to the stage ST by the fixing member GR may be movable on the stage ST. For example, one edge of the outermost portions OMP1 of the donor 300 may be fixed to the stage ST by the fixing member GR. For example, two adjacent edges of the outermost portions of the donor 300 may be fixed to the stage ST by the fixing member GR. The stage ST may not suck the donor 300 with vacuum, and the stage ST and the donor 300 may be physically fixed by the fixing member GR.

The wafer 200 is fixed to the head HD (S132). One surface TS3 of the wafer 200 may be fixed to the head HD. For example, one entire surface TS3 of the wafer 200 may be fixed to the head HD by the vacuum sucking method or by a fixing member. In this case, the stage ST moves to the head HD to suck the head HD and the wafer 200 with vacuum or the head HD moves to the wafer 200 to suck the head HD and the wafer 200 with vacuum.

Next, referring to FIG. 7F, the stage ST and the fixing member GR move to the Z-axis direction to detach the wafer 200 and the donor 300 and the wafer 200 and the head HD move to the X-axis direction with respect to a center line C (S133).

The stage ST and the fixing member GR move to the Z-direction, specifically, move to be spaced apart from the head HD to separate the wafer 200 and the donor 300. The donor 300 is fixed between the stage ST and the fixing member GR and the wafer 200 is fixed to the head HD. Accordingly, when the stage ST and the fixing member GR move to be spaced apart from the head HD, the donor 300 and the wafer 200 may be separated from each other.

At this time, only the stage ST and the fixing member GR move, but the support member 400 does not move so that the support member 400 may support the other one of outermost portions OMP2 of the donor 300 in a fixed state. Accordingly, distances in a Z-axis direction between the head HD and the support member 400 may be maintained to be the same during the detachment process.

Further, the wafer 200 and the head HD may move to the X-axis direction, specifically, to be spaced apart from the support member 400 with respect to the center line C. This is to offset a tensile stress to be applied to the donor 300 due to the reduced adhesive strength in a latter part of the detachment process.

In the meantime, in order to reduce or minimize a tensile stress to be applied to the donor 300 in the latter part of the detachment process of the wafer 200 and the donor 300, a step of moving the stage ST and the fixing member GR to the Z-axis direction and a step of moving the wafer 200 and the head HD to the X-axis direction may be concurrently or simultaneously performed.

In this case, the wafer 200 which is fixed to the head HD by the vacuum sucking method may maintain a state in which one entire surface is attached to the head HD. In contrast, the donor 300 is fixed to the stage ST by one of outermost portions OMP1 and is disposed in the other one of outermost portions OMP2. Therefore, the other one which is configured to be movable without being fixed to the stage ST may be movable along the wafer 200 and the head HD. In a state in which the one entire surface of the wafer 200 is fixed to the head HD and only one of outermost portions of the donor 300 is fixed to the stage ST, and the support member 400 fixed to the other one of the outermost portions is disposed, when the wafer 200 and the donor 300 move to be spaced apart from each other, the wafer 200 and the donor 300 may be detached to be linearly separated.

For example, in a state in which a left edge of the donor 300 is fixed to the stage ST and the support member 400 is disposed in a right edge, when the stage ST and the fixing member GR move to the Z-axis direction, the other part of the donor 300 bonded to the wafer 200 may be movable in the Z-axis direction along the wafer 200 and the head HD. First, when the stage ST and the fixing member GR begin to move to the Z-axis direction, the left edge of the donor 300 which cannot move together with the wafer 200 may be first separated from the wafer 200. As the head HD and the wafer 200 are gradually spaced apart from the donor 300, one part of the donor 300 adjacent to the left edge of the donor 300 may begin to be separated from the wafer 200.

At this time, only the stage ST and the fixing member GR move to the Z-axis direction so that the support member 400 supports the right edge of the donor 300 in a fixed state. At this time, the tensile stress to be applied to the right edge of the donor 300 with respect to FIG. 7F may be relieved by concurrently or simultaneously moving the stage ST and the fixing member GR to the Z-axis direction and moving the head HD to the X-axis direction away from the support member 400. Accordingly, the plurality of light emitting diodes LED adhered to the plurality of chip bumps 331 of the donor 300 also in the latter part of the detachment process may be separated from the wafer 200 in the unit of lines so that the defective chip transfer may be reduced.

During the linear separation process, in order to reduce interruption between the dam DM of the wafer 200 and the light emitting diode LED disposed at the outermost periphery of the active area 200A, an interval between the dam DM and the light emitting diode LED may be formed to be equal to or larger than an interval from the outer periphery of one light emitting diode LED to an outer periphery of an adjacent light emitting diode LED. As described above, when the wafer 200 and the donor 300 are detached, the plurality of light emitting diodes LED may be separated from the wafer 200 in the unit of lines. At this time, when a sufficient interval is not ensured between the dam DM and the active area 200A, during the process of sequentially separating the light emitting diode LED at the outermost periphery of the active area 200A transferred to the donor 300 and the dam DM, the outermost light emitting diode LED and the dam DM of the wafer 200 may interfere with each other. If a surface separation method of separating the donor 300 and the front surface of the wafer 200 at one time is used, the outermost light emitting diode LED and the dam DM may not interfere with each other. However, in the transfer device and the transfer method of a light emitting diode LED and the method for manufacturing a display device 100 using the same, according to the exemplary embodiment of the present disclosure, the wafer 200 and the donor 300 are detached by the linear separation method. Therefore, interference may occur between the outermost light emitting diode LED and the dam DM in which the linear separation is performed finally, which leads to the defective transfer of the plurality of light emitting diodes LED. Therefore, the interference between the dam DM and the plurality of light emitting diodes LED generated when the wafer 200 and the donor 300 are detached may be reduced by ensuring a sufficient interval between the dam DM of the outer peripheral area 200B of the wafer 200 and the plurality of light emitting diodes LED of the active area 200A.

Finally, referring to FIG. 7G, a secondary transfer process is performed to transfer the plurality of light emitting diodes LED on the donor 300 to the display panel PN to complete a manufacturing process of the display device 100. At this time, the display panel PN is a display panel PN in which a circuit for driving the plurality of light emitting diodes LED, for example, the driving transistor 120 and the plurality of wiring lines are completely formed.

First, the donor 300 in which a plurality of light emitting diodes LED is disposed and the display panel PN are input to the process equipment. Next, the donor 300 and the display panel PN are aligned.

At this time, the donor 300 and the display panel PN may be aligned with respect to the second alignment key AK2 which is transferred from the wafer 200 to the donor 300 and the alignment key AK of the display panel PN.

The plurality of light emitting diodes LED and the second alignment key AK2 disposed on the donor 300 are transferred by the same process. Therefore, the relative position of the plurality of light emitting diodes LED and the second alignment key AK2 may be constant. Therefore, when the donor 300 and the display panel PN are aligned with respect to the second alignment key AK2 which has a constant relative position with the plurality of light emitting diodes LED, an alignment accuracy to transfer the plurality of light emitting diodes LED in a correct position may be improved. Accordingly, when the plurality of light emitting diodes LED of the donor 300 is transferred to the display panel PN, the donor 300 and the display panel PN may be aligned with respect to the second alignment key AK2. However, even though in the present disclosure, it has been described that the donor 300 and the display panel PN are aligned with respect to the second alignment key AK2, the donor 300 and the display panel PN may be aligned with respect to another component, but is not limited thereto.

The alignment key AK of the display panel PN which is aligned with the second alignment key AK2 on the donor 300 may be any one of components formed on the display panel PN or may be separately formed to be disposed. For example, when the alignment key AK is any one of components formed on the display panel PN, a reflection layer which overlaps the plurality of light emitting diodes LED, some of a plurality of wiring lines disposed to drive the plurality of light emitting diodes LED, and the like, among components formed on the display panel PN, may serve as the alignment key AK. Further, when the alignment key AK is separately formed to be disposed, the alignment key AK may be a pattern or a structure formed on the display panel PN, but is not limited thereto.

Next, when the alignment of the donor 300 and the display panel PN is completed, the donor 300 and the display panel PN are bonded (S140). Next, the plurality of light emitting diodes LED is transferred to the display panel PN (S150). After transferring the plurality of light emitting diodes LED of the donor 300 to the display panel PN, the donor 300 and the display panel PN are detached (S160).

In some cases, a rigid substrate may be used as the donor 300, rather than the flexible substrate. For example, the donor 300 may be configured by a hard material, instead of a material, such as polydimethylsiloxane (PDMS). However, when the donor 300 is a hard substrate, there are problems in that it is difficult to configure the donor 300 with a large size due to the thickness variation and the number of times of transferring may increase. In contrast, when the donor 300 is configured by a flexible substrate, the area of the donor 300 may be increased and the damage of the light emitting diode LED may be reduced or minimized. Therefore, the flexible substrate may be used as the donor 300.

In the meantime, when the donor which is a flexible substrate is detached from the wafer by the surface separation method, the defective transfer of the plurality of light emitting diodes may occur. For example, in order to detach the donor and the wafer by the surface separation method, the detachment process may be performed in a state in which one entire surface of the donor is fixed to the stage and one entire surface of the wafer is fixed to the head. At this time, when one entire surface of the donor which is a flexible substrate is fixed to the stage by the vacuum sucking method, the donor is wrinkled, which may cause the defective transfer of the plurality of light emitting diodes. Further, a surface tension generated during surface separation or the external force caused by vacuum suction affects the fine-sized light emitting diode so that the light emitting diode may be transferred in an overturned or tilted state, or in a rotated state. The defective transfer may be randomly generated in the surface separation area, which leads to the reduction in the yield and the increase in the process cost.

Therefore, in the transfer device and the transfer method of a light emitting diode LED and a method for manufacturing a display device 100 using the same, according to the exemplary embodiment of the present disclosure, one end of the donor 300 which is a flexible substrate is physically fixed and the other end is supported. Therefore, the external force due to the vacuum suction is reduced or minimized and the donor 300 is naturally linearly separated from the wafer 200 during the detachment process so that the surface tension may be reduced or minimized.

However, as the detachment of the wafer and the donor proceeds, the number of chips remaining on the wafer is reduced so that a contact area of the donor and the wafer is reduced, which may reduce the adhesive strength of the wafer and the donor. Accordingly, when the adhesive strength between the wafer and the donor is reduced below a specific value, the wafer and the donor are separated so that there may be an area in which surface separation, rather than the linear separation is performed in the latter part of the detachment process.

Specifically, when the donor is a flexible substrate, an end of the donor which is not fixed to the stage receives not only a pulling force in the Z-axis direction by the stage, but also a pulling force toward the fixing member. That is, the donor is fixed to the stage by pressurizing one end of the donor by the fixing member so that the other end of the donor receives a pulling force toward one end direction of the donor. Accordingly, as the latter part of the detachment process progresses, the tensile stress on the other end of the donor increases, which may cause an area in which the other end of the donor is surface-separated or a problem in that the donor fails to be sequentially separated, but the other end of the donor is separated before the center area of the donor. Therefore, defects that the light emitting diode rotates, tilts, shifts, or flips may occur due to the force generated at the moment when the other end of the donor is surface-separated or the other end of the donor is separated before the center area of the donor.

Therefore, in the transfer device and the transfer method of a light emitting diode LED and a method for manufacturing a display device 100 using the same, according to the exemplary embodiment of the present disclosure, the fixing member GR fixes one of outermost portions of the donor 300 and the support member 400 supports the other one of outermost portions of the donor 300. At this time, the support member 400 and the head HD do not move to the Z-axis direction so that the distance of the support member 400 and the head HD in the Z-axis direction may be always maintained constantly. Therefore, in the transfer device and the transfer method of a light emitting diode LED and a method for manufacturing a display device 100 using the same, according to the exemplary embodiment of the present disclosure, the surface separation of the other end of the donor 300 by the pulling force toward the fixing member GR or separation before the center area may be reduced or minimized.

Further, in the transfer device and the transfer method of a light emitting diode LED and a method for manufacturing a display device 100 using the same, according to the exemplary embodiment of the present disclosure, the stage ST and the fixing member GR may move to the Z-axis direction and the wafer 200 and the head HD may move to the X-axis direction, concurrently or simultaneously. Specifically, the wafer 200 and the head HD may move to a direction in which the fixing member GR is disposed. Therefore, the tensile stress pulling to the fixing member GR which is applied to the other end of the donor 300 disposed on the support member 400 may be reduced. Accordingly, in the transfer device and the transfer method of a light emitting diode LED and a method for manufacturing a display device 100 using the same, according to the exemplary embodiment of the present disclosure, the tensile stress applied to the other end of the outermost portions of the donor 300 is relieved to reduce or minimize the surface separation of the other end of the donor 300 or separation before the center area may be reduced or minimized.

Accordingly, in the transfer device and the transfer method of a light emitting diode LED and a method for manufacturing a display device 100 using the same, according to the exemplary embodiment of the present disclosure, the wafer 200 and the donor 300 are detached by the linear separation method to reduce the defective transfer of the plurality of light emitting diodes LED.

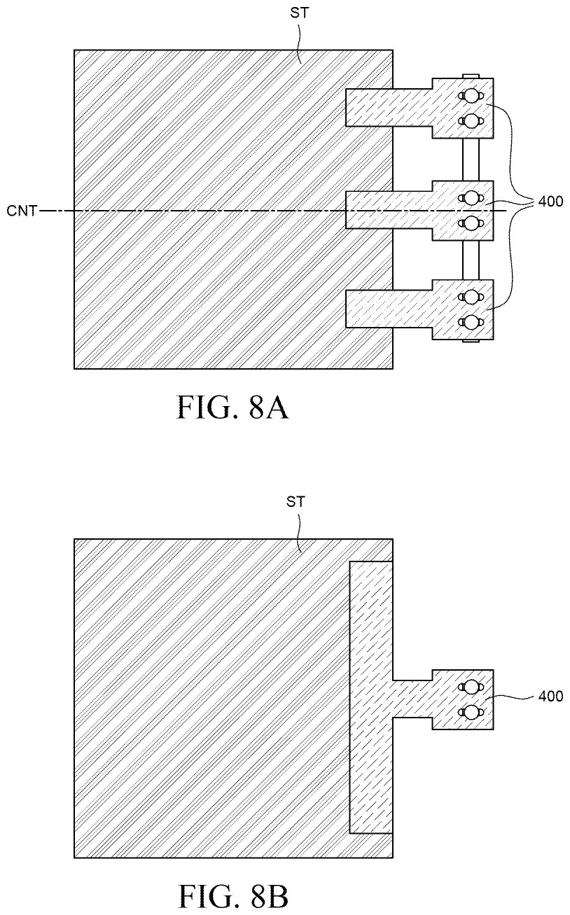

FIGS. 8A and 8B are schematic cross-sectional views for explaining a transfer device and a transfer method of a light emitting diode according to another exemplary embodiment of the present disclosure. In the transfer device and the transfer method of a light emitting diode of FIGS. 8A and 8B, only a support member is different from that of the transfer device and the transfer method of a light emitting diode of FIGS. 1 to 7G. However, the other components are substantially the same so that a redundant description will be omitted.

First, referring to FIG. 8A, a plurality of support members 400 may be provided. That is, the support member 400 may be configured by a plurality of support members 400 with a plate shape. Even though in FIG. 8A, it is illustrated that three support members 400 are provided, the number of support members 400 is not limited thereto.

The support member 400 may be disposed so as to correspond to the other one of outermost portions of the donor 300. For example, as illustrated in FIG. 8A, one of the plurality of support members 400 may be located at the center CNT of the stage ST and two remaining support members 400 may be disposed to be located on both sides with respect to the center CNT of the stage ST.

Further, referring to FIG. 8B, one support member 400 may be provided. That is, the support member 400 may be configured by a single support member 400 with a plate shape.

The support member 400 may be disposed so as to correspond to the other one of outermost portions of the donor 300. At this time, the support member 400 may be disposed so as to correspond to one side of the other one of outermost portions of the donor 300, but is not limited thereto.

In the transfer device and the transfer method of a light emitting diode LED according to another exemplary embodiment of the present disclosure, a plurality of support members 400 may be provided or the support member may be disposed so as to correspond to one side of the other one of outermost portions of the donor 300. Therefore, the support member 400 may support a more area of the light emitting diode LED so that an area of the donor 300 fixed between the support member 400 and the head HD may be increased. Accordingly, in the transfer device and the transfer method of a light emitting diode LED according to another exemplary embodiment of the present disclosure, the linear separation of the donor 300 and the wafer 200 may be maintained until the end of the detachment process.

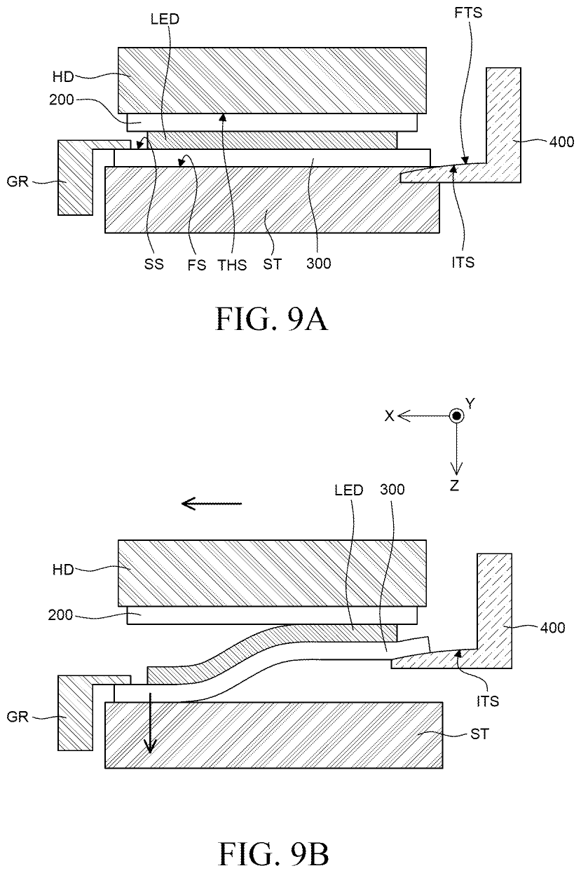

FIGS. 9A and 9B are schematic cross-sectional views for explaining a transfer device and a transfer method of a light emitting diode according to still another exemplary embodiment of the present disclosure. In the transfer device and the transfer method of a light emitting diode of FIGS. 9A and 9B, only a support member is different from that of the transfer device and the transfer method of a light emitting diode of FIGS. 1 to 7G. However, the other components are substantially the same so that a redundant description will be omitted.

Referring to FIGS. 9A and 9B, the support member 400 may have a plate shape. That is, the support member 400 has an inclined top surface ITS and the donor 300 may be disposed on the inclined top surface ITS of the support member 400. Specifically, the inclination of the support member 400 may be sequentially increased from the fixing member GR to the support member 400.

Referring to FIG. 9A, a stage ST has a first surface FS. This first surface FS was also referred to as the top surface TS4 of the stage. In operation, the stage is configured to load a wafer 200 and a donor 300 on the first surface FS of the stage ST. Here, the donor 300 has a second surface SS. The second surface SS of the donor 300 was also referred to as the top surface TS2 of the donor 300.

As shown, the head HD is configured to fix a third surface THS of the wafer 200. The third surface THS was also referred to as one surface TS3 of the wafer 200. The third surface THS of the wafer 200 is opposite to and faces the first surface FS of the stage ST. In addition, the second surface SS of the donor 300 is between the third surface THS of the wafer 200 and the first surface FS of the stage ST.

Referring to FIG. 9A, a fixing member GR is adjacent to the stage ST. The fixing member GR is configured to contact the second surface SS of one of the outermost portions OMP of the donor 300 to the stage ST and fix the donor 300 to the stage ST. The support member 400 has a fourth surface FTS. The fourth surface FTS was also referred to as a top surface TS1 of the support member 400. The support member, in operation, is configured to be contact the donor 300 at the fourth surface FTS of the support member 400. As shown in FIGS. 7F and 9A, the fourth surface FTS can be either a flat planar surface or an inclined surface having a selected curvature.

According to the transfer device and the transfer method of a light emitting diode LED according to another exemplary embodiment of the present disclosure, during the detachment process of the wafer 200 and the donor 300, the support member 400 supports the other one of the outermost portions of the donor 300 in a fixed state. Therefore, the linear separation may be maintained until the end of the detachment process.

Further, in the transfer device and the transfer method of a light emitting diode LED according to another exemplary embodiment of the present disclosure, the support member 400 has a plate shape with an inclined top surface. Accordingly, the donor 300 disposed on the support member 400 may also have an inclined shape due to the inclination of the support member 400. Accordingly, in the transfer device and the transfer method of a light emitting diode LED according to still another exemplary embodiment of the present disclosure, the tensile stress to be applied to the donor 300 during the detachment process of the wafer 200 and the donor 300 is more relieved so that it may be effective to maintain the linear separation.

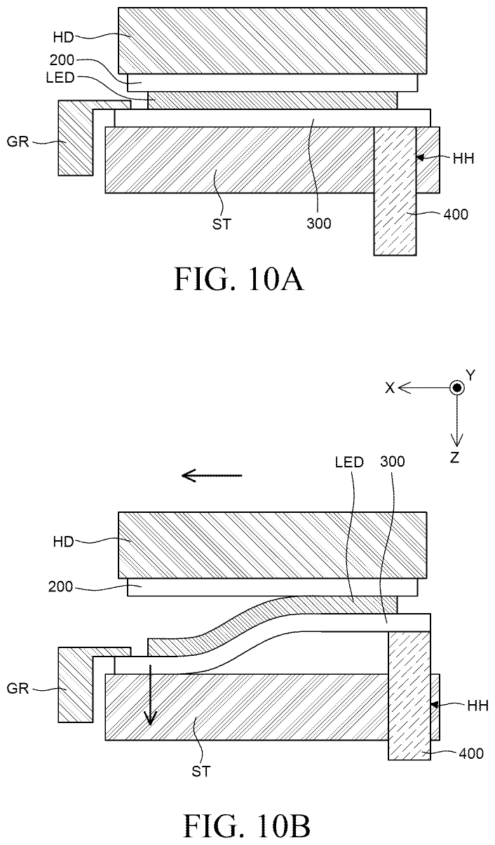

FIGS. 10A and 10B are schematic cross-sectional views for explaining a transfer device and a transfer method of a light emitting diode according to still another exemplary embodiment of the present disclosure. In the transfer device and the transfer method of a light emitting diode of FIGS. 10A and 10B, only a stage and a support member are different from those of the transfer device and the transfer method of a light emitting diode of FIGS. 1 to 7G. However, the other components are substantially the same so that a redundant description will be omitted.

Referring to FIGS. 10A and 10B, the stage ST may include a hole HH in which the support member 400 is disposed. The hole HH of the stage ST may be disposed so as to correspond to the other end of one side in which the fixing member GR is disposed, but is not limited thereto.

The support member 400 may have a columnar shape. For example, the support member 400 may have various columnar shapes, such as a cylindrical shape or a polygonal columnar shape. At this time, the support member 400 may be configured by a single support member.

The support member 400 may be disposed in the hole HH of the stage ST. The support member 400 may be fixed without moving in the hole HH of the stage ST during the detachment process of the wafer 200 and the donor 300. That is, the support member 400 is configured so as not to move in the X-axis, Y-axis, and Z-axis directions during the detachment process of the wafer 200 and the donor 300 and may maintain an interval with the head HD.

In the transfer device and the transfer method of a light emitting diode LED according to another exemplary embodiment of the present disclosure, during the detachment process of the wafer 200 and the donor 300, the support member 400 supports the other one of outermost portions of the donor 300 in a fixed state. Therefore, the linear separation may be maintained until the end of the detachment process.

Further, in the transfer device and the transfer method of a light emitting diode LED according to another exemplary embodiment of the present disclosure, the support member 400 has a columnar shape which is disposed in the hole HH of the stage ST. Therefore, the support member 400 is not disposed at the outside of the stage ST so that a volume of a transfer device of a light emitting diode LED may be reduced.

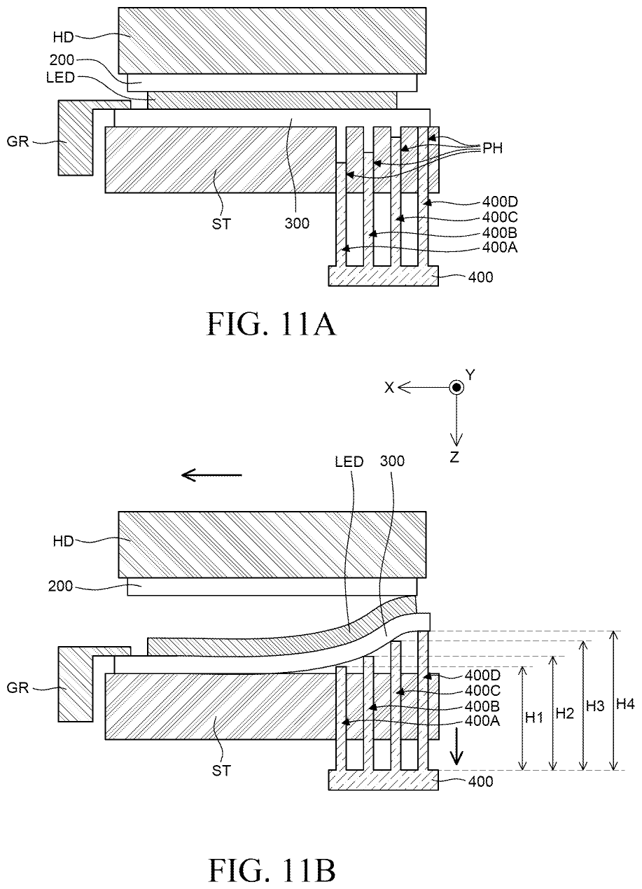

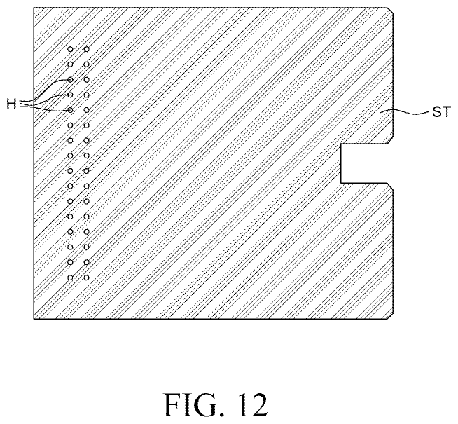

FIGS. 11A and 11B are schematic cross-sectional views for explaining a transfer device and a transfer method of a light emitting diode according to still another exemplary embodiment of the present disclosure. In the transfer device and the transfer method of a light emitting diode of FIGS. 11A and 11B, only a stage and a support member are different from those of the transfer device and the transfer method of a light emitting diode of FIGS. 1 to 7G. However, the other components are substantially the same so that a redundant description will be omitted.

Referring to FIGS. 11A and 11B, the stage ST may include a plurality of holes PH in which the support member 400 is disposed. The plurality of holes PH of the stage ST may be disposed so as to correspond to the other side of one side in which the fixing member GR is disposed, but is not limited thereto.

The support member 400 may have a columnar shape. For example, the support member 400 may have various columnar shapes, such as a cylindrical shape or a polygonal columnar shape.

The support member 400 may be configured by a plurality of columnar structures. The columnar structures as shown in FIGS. 11A and 11B may also be referred to as sub-support members extending towards the head HD (or towards the donor 300). That is, the support member 400 may be configured by a plurality of sub-support members 400A, 400B, 400C, 400D with a columnar shape. In some embodiments, a height of each sub-support member of the plurality of sub-support members 400A, 400B, 400C, 400D may be different from each other. For example, a first sub-support member 400A may have a first height H1, a second sub-support member 400B may have a second height H2, a third sub-support member 400C may have a third height H3, and a fourth sub-support member 400D may have a fourth height H4. As shown, the height of the plurality sub-support members 400A, 400B, 400C, 400D may have the following relationship H1<H2<H3<H4. That is, a height of each sub-support member of the plurality of sub-support members becomes gradually higher as each sub-support member is disposed farther away from the fixing member GR. Even though in FIGS. 11A and 11B, it is illustrated that four support members 400 are provided, the number of support members is not limited thereto.

At this time, a height of top surfaces of the plurality of columnar structures 400A, 400B, 400C, 400D may be sequentially increased from the fixing member GR to the support member 400. That is, as illustrated in FIG. 11A, the height of the top surfaces of the support members may be increased from a support member disposed at a left side to a support member disposed at a right side. Therefore, as illustrated in FIG. 11B, during the detachment process, the donor 300 also may have an inclined shape due to the difference in the heights of the top surfaces of the plurality of columnar structures.

The support member 400 may be disposed in the plurality of holes of the stage ST. The support member 400 may be fixed without moving in the plurality of holes PH of the stage ST during the detachment process of the wafer 200 and the donor 300. That is, the support member 400 is configured so as not to move in the X-axis, Y-axis, and Z-axis directions during the detachment process of the wafer 200 and the donor 300 and may maintain an interval with the head HD.

In the transfer device and the transfer method of a light emitting diode LED according to another exemplary embodiment of the present disclosure, during the detachment process of the wafer 200 and the donor 300, the support member 400 supports the other one of outermost portions of the donor 300 in a fixed state. Therefore, the linear separation may be maintained until the end of the detachment process.

Accordingly, in the transfer device and the transfer method of a light emitting diode LED according to still another exemplary embodiment of the present disclosure, the tensile stress to be applied to the donor 300 during the detachment process of the wafer 200 and the donor 300 is more relieved by the inclination formed by the height difference of the plurality of columnar structures. Therefore, it may be effective to maintain the linear separation.

FIG. 12 is a schematic plan view of a stage for explaining a transfer device and a transfer method of a light emitting diode according to still another exemplary embodiment of the present disclosure. In the transfer device and the transfer method of a light emitting diode of FIG. 12, only a stage is different from that of the transfer device and the transfer method of a light emitting diode of FIGS. 1 to 7G. However, the other components are substantially the same so that a redundant description will be omitted.

Referring to FIG. 12, a hole H for vacuum suction may be disposed at one side of the stage ST. The step S131 of physically fixing one of outermost portions of the donor 300 with the fixing member GR may further include a step of sucking the stage ST and the donor 300 with vacuum to increase a fixing force between the donor 300 and the stage ST.

At this time, the hole H of the stage ST for vacuum suction may be disposed to be adjacent to the fixing member GR more than the support member 400. In the meantime, even though it is illustrated that the stage ST includes one groove in FIG. 12, it is not limited hereto.

In the transfer device and the transfer method of a light emitting diode LED according to still another exemplary embodiment of the present disclosure, during the detachment process of the wafer 200 and the donor 300, the support member 400 supports the other one of the outermost portions of the donor 300 in a fixed state. Therefore, the linear separation may be maintained until the end of the detachment process.

Further, in the transfer device and the transfer method of a light emitting diode LED according to still another exemplary embodiment of the present disclosure, a hole H for vacuum suction of the donor 300 is disposed in the stage ST to be adjacent to the fixing member GR more than the support member 400. Accordingly, the fixing force between the donor 300 and the stage ST may be increased in an area adjacent to the fixing member GR.

The exemplary embodiments of the present disclosure can also be described as follows:
According to an aspect of the present disclosure, there is provided a transfer method of a light emitting diode. The transfer method of the light emitting diode includes bonding a wafer in which a plurality of light emitting diodes is formed and a donor, transferring the plurality of light emitting diodes to the donor and detaching the wafer from the donor. The detaching of the wafer from the donor includes loading the bonded wafer and donor on a stage and a support member, fixing one of outermost portions of the donor by a fixing member, fixing one surface of the wafer to a head, moving the stage and the fixing member to a Z-axis direction and moving the wafer and the head to an X-axis direction.

In the loading of the bonded wafer and donor on a stage, the support member may be disposed in a groove of the stage corresponding to the other one of the outermost portions of the donor.

The moving of the stage and the fixing member to a Z-axis direction may include moving the stage and the fixing member to be spaced apart from the head in a state in which the support member is fixed.

In the moving of the stage and the fixing member to a Z-axis direction and the moving of the wafer and the head to an X-axis direction, distances between the head and the support member in the Z-axis direction may be the same.

The moving of the wafer and the head to an X-axis direction may include moving the wafer and the head to be spaced apart from the support member.

The moving of the stage and the fixing member to a Z-axis direction and the moving of the wafer and the head to an X-axis direction may be concurrently or simultaneously performed.

The donor may include a base layer and a resin layer which is disposed on the base layer and include a transferring area and a non-transferring area and an end of the support member overlap the base layer and the resin layer and be disposed in the non-transferring area.

One support member may be provided and the support member be disposed so as to correspond to a center of the donor at the other one of the outermost portions of the donor.

One support member may be provided and the support member be disposed so as to correspond to one side of the other one of the outermost portions of the donor.

A plurality of support members may be provided and be disposed so as to correspond to the other one of the outermost portions of the donor.

The fixing of one of outermost portions of the donor by a fixing member may include sucking the donor with the stage in an area more adjacent to the fixing member than the support member.

The support member may have a plate shape or a columnar shape.

The support member may include a plurality of columnar structures and heights of top surfaces of the plurality of columnar structures may be sequentially increased from the fixing member to the support member.

The support member may have an inclined plate shape and the inclination may be sequentially increased from the fixing member to the support member.

According to an aspect of the present disclosure, there is provided a method for manufacturing a display device. The method for manufacturing the display device includes bonding a wafer and a donor, transferring a plurality of light emitting diodes of the wafer to the donor, detaching the wafer from the donor, bonding the donor on which the plurality of light emitting diodes is disposed and the display panel, transferring the plurality of light emitting diodes of the donor to the display panel and detaching the display panel from the donor. The detaching of the wafer from the donor includes loading the bonded wafer and donor on a stage, fixing one of outermost portions of the donor by a fixing member, fixing one surface of the wafer to a head, moving the stage and the fixing member to a Z-axis direction and moving the wafer and the head to an X-axis direction.

The moving of the stage and the fixing member to a Z-axis direction may includes moving the stage and the fixing member to be spaced apart from the head in a state in which the support member is fixed.

In the moving of the stage and the fixing member to a Z-axis direction and the moving of the wafer and the head to an X-axis direction, distances between the head and the support member in the Z-axis direction may be the same.

The moving of the wafer and the head to an X-axis direction may include moving the wafer and the head to be spaced apart from the support member.

The moving of the stage and the fixing member to a Z-axis direction and the moving of the wafer and the head to an X-axis direction may be concurrently or simultaneously performed.

According to an aspect of the present disclosure, there is provided a transfer device of a light emitting diode. The transfer device of the light emitting diode includes a stage on which a wafer and a donor are loaded, a head configured to fix one surface of the wafer, a fixing member configured to fix one of outermost portions of the donor to the stage and a support member configured to be disposed in a groove of the stage to support the donor.

The wafer and the donor may be spaced apart from each other by moving the wafer and the head to an X-axis direction and moving the stage and the fixing member to a Z-axis direction.

The stage and the fixing member may be configured to move to a Z-axis direction to separate the donor from the wafer.

The head may be configured to move to an X-axis direction.

The stage and the fixing member may be configured to move concurrently or simultaneously with the head.

The stage may include a plurality of suction holes configured to suck the donor in an area more adjacent to the fixing member than the support member.

One support member may be provided and the support member may be disposed so as to correspond to a center of the donor at the other one of the outermost portions of the donor.

One support member may be provided and the support member may be disposed so as to correspond to one side of the other one of the outermost portions of the donor.

A plurality of support members may be provided and be disposed so as to correspond to the other one of the outermost portions of the donor.

The support member may include a plurality of columnar structures and heights of top surfaces of the plurality of columnar structures may be sequentially increased from the fixing member to the support member.

The support member may have an inclined plate shape and the inclination may be sequentially increased from the fixing member to the support member.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A transfer method of a light emitting diode, comprising:
bonding a wafer and a donor, the wafer in which a plurality of light emitting diodes is formed;
transferring the plurality of light emitting diodes to the donor; and
detaching the wafer from the donor,
wherein the detaching of the wafer from the donor includes:
loading the bonded wafer and donor on a stage and a support member;
fixing one of outermost portions of the donor by a fixing member;
fixing one surface of the wafer to a head;
moving the stage and the fixing member to a first direction; and
moving the wafer and the head to a second direction transverse to the first direction.

2. The transfer method of a light emitting diode according to claim 1, wherein in the loading of the bonded wafer and donor on a stage, the support member is disposed in a groove of the stage corresponding to the other one of the outermost portions of the donor.

3. The transfer method of a light emitting diode according to claim 1, wherein the moving of the stage and the fixing member to a first direction includes: moving the stage and the fixing member to be spaced apart from the head in a state in which the support member is fixed.

4. The transfer method of a light emitting diode according to claim 3, wherein in the moving of the stage and the fixing member to a first direction and the moving of the wafer and the head to a second direction, distances between the head and the support member in the first direction are the same.

5. The transfer method of a light emitting diode according to claim 1, wherein the moving of the wafer and the head to a second direction includes: moving the wafer and the head to be spaced apart from the support member.

6. The transfer method of a light emitting diode according to claim 1, wherein the moving of the stage and the fixing member to a first direction and the moving of the wafer and the head to a second direction are concurrently performed.

7. The transfer method of a light emitting diode according to claim 1, wherein the donor includes a base layer and a resin layer which is disposed on the base layer and includes a transferring area and a non-transferring area and an end of the support member overlaps the base layer and the resin layer and is disposed in the non-transferring area.

8. The transfer method of a light emitting diode according to claim 1, wherein one support member is provided and the support member is disposed so as to correspond to a center of the donor at the other one of the outermost portions of the donor.

9. The transfer method of a light emitting diode according to claim 1, wherein one support member is provided and the support member is disposed so as to correspond to one side of the other one of the outermost portions of the donor.

10. The transfer method of a light emitting diode according to claim 1, wherein a plurality of support members is provided and is disposed so as to correspond to the other one of the outermost portions of the donor.

11. The transfer method of a light emitting diode according to claim 1, wherein the fixing of one of outermost portions of the donor by a fixing member includes: sucking the donor with the stage in an area more adjacent to the fixing member than the support member.

12. The transfer method of a light emitting diode according to claim 1, wherein the support member has a plate shape or a columnar shape.

13. The transfer method of a light emitting diode according to claim 1, wherein the support member includes a plurality of columnar structures and heights of top surfaces of the plurality of columnar structures are sequentially increased from the fixing member to the support member.

14. The transfer method of a light emitting diode according to claim 1, wherein the support member has an inclined plate shape and the inclination is sequentially increased from the fixing member to the support member.

15. A method for manufacturing a display device, comprising:
bonding a wafer and a donor, the wafer having a plurality of light emitting diodes;
transferring the plurality of light emitting diodes from the wafer to the donor;
detaching the wafer from the donor;
bonding the donor on which the plurality of light emitting diodes is disposed and the display panel;
transferring the plurality of light emitting diodes from the donor to the display panel; and
detaching the display panel from the donor,
wherein the detaching of the wafer from the donor includes:
loading the bonded wafer and donor on a stage;
fixing one of outermost portions of the donor by a fixing member;
fixing one surface of the wafer to a head;
moving the stage and the fixing member to a first direction; and
moving the wafer and the head to a second direction transverse to the first direction.

16. The method for manufacturing a display device according to claim 15, wherein the moving of the stage and the fixing member to a first direction includes: moving the stage and the fixing member to be spaced apart from the head in a state in which the support member is fixed.

17. The method for manufacturing a display device according to claim 16, wherein in the moving of the stage and the fixing member to a first direction and the moving of the wafer and the head to a second direction, distances between the head and the support member in the first direction are the same.

18. The method for manufacturing a display device according to claim 15, wherein the moving of the wafer and the head to a second direction includes: moving the wafer and the head to be spaced apart from the support member.

19. The method for manufacturing a display device according to claim 15, wherein the moving of the stage and the fixing member to a first direction and the moving of the wafer and the head to a second direction are concurrently performed.

20. A transfer device of a light emitting diode, comprising:
a stage having a first surface, the stage configured to load a wafer and a donor on the first surface of the stage, the donor having a second surface at outermost portions;
a head configured to fix a third surface of the wafer, the third surface of the wafer opposite to and facing the first surface of the stage, the second surface of the donor being between the third surface of the wafer and the first surface of the stage;
a fixing member adjacent to the stage, the fixing member configured to contact the second surface of one of the outermost portions of the donor to the stage and fix the donor to the stage; and
a support member having a fourth surface, the support member configured to contact the donor at the fourth surface of the support member.

21. The transfer device of a light emitting diode according to claim 20, wherein the stage and the fixing member is configured to move in a first direction to gradually increase a distance between the head and the stage,
wherein the head is configured to move in a second direction transverse to the first direction, and
wherein, in operation, the wafer and the donor are gradually spaced apart from each other by moving the wafer and the head to the second direction and moving the stage and the fixing member to the first direction.

22. The transfer device of a light emitting diode according to claim 21, wherein the stage and the fixing member are configured to move concurrently with the head.

23. The transfer device of a light emitting diode according to claim 20, further comprising a plurality of suction holes included in the stage, the plurality of suction holes configured to suck the donor in an area more adjacent to the fixing member than the support member.

24. The transfer device of a light emitting diode according to claim 20, wherein one support member is provided and the support member is disposed so as to correspond to a center of the donor at the other one of the outermost portions of the donor.

25. The transfer device of a light emitting diode according to claim 20, wherein one support member is provided and the support member is disposed so as to correspond to one side of the other one of the outermost portions of the donor.

26. The transfer device of a light emitting diode according to claim 20, wherein a plurality of support members is provided and is disposed so as to correspond to the other one of the outermost portions of the donor.

27. The transfer device of a light emitting diode according to claim 20, wherein the support member includes a plurality of columnar structures and heights of top surfaces of the plurality of columnar structures are sequentially increased from the fixing member to the support member.

28. The transfer device of a light emitting diode according to claim 20, wherein the support member has an inclined plate shape and the inclination is sequentially increased from the fixing member to the support member.

29. The transfer device of a light emitting diode according to claim 20, wherein the fourth surface of the support member is either a flat surface or an inclined surface.

30. The transfer device of a light emitting diode according to claim 20, further comprising a groove in the stage,
wherein the groove is configured to provide a space for the support member.

31. The transfer device of a light emitting diode according to claim 20, further comprising at least one hole in the stage,
wherein the at least one hole is configured to provide a space for the support member.

32. The transfer device of a light emitting diode according to claim 31, wherein the support member includes a plurality of sub-support members extending towards the head.

33. The transfer device of a light emitting diode according to claim 31, wherein a height of each sub-support member of the plurality of sub-support members is different from each other.

34. The transfer device of a light emitting diode according to claim 31, wherein a height of each sub-support member of the plurality of sub-support members becomes gradually higher as each sub-support member is disposed farther away from the fixing member.
